(19) United States
(12) Patent Application Publication
(10) Pub. No.: US 2026/0369529 A1
(43) Pub. Date: Nov. 19, 2026

(54) SYSTEM OF INDUCING PLASMA USING HARMONIC WAVE AND METHOD OF INDUCING PLASMA USING THE SAME

(71) Applicant: EN2CORE TECHNOLOGY, INC, Daejeon (KR)

(72) Inventors: Yeong Hoon SOHN, Daejeon (KR); Xuan Van THAI, Daejeon (KR); Dong JEGAL, Daejeon (KR); Jin HUH, Daejeon (KR)

(73) Assignee: EN2CORE TECHNOLOGY, INC, Daejeon (KR)

(21) Appl. No.: 19/721,152

(22) Filed: Jun. 26, 2026

Related U.S. Application Data
(63) Continuation of application No. PCT/KR2025/000702, filed on Jan. 13, 2025.

(30) Foreign Application Priority Data
Jan. 17, 2024 (KR) 10-2024-0007166

(51) Int. Cl. H01J 37/32; H05H 1/46

(52) U.S. Cl. CPC H01J 37/32174; H01J 37/3211; H01J 37/32128; H01J 37/32165; H05H 1/4652

(57) ABSTRACT

The present invention relates to a system for inducing plasma using harmonic waves and a method of inducing plasma using the same and, more specifically, to a plasma induction system and a plasma induction method using the same in which the resonant frequency of an antenna structure for forming an inductively coupled plasma is designed based on a harmonic frequency of a driving frequency of an input voltage.

### CROSS REFERENCE TO RELATED APPLICATIONS

The present application is a continuation of International Application No. PCT/KR2025/000702 filed on Jan. 13, 2025, which claims priority to Korean Patent Application No. 10-2024-0007166, filed on Jan. 17, 2024, the entire contents of which are incorporated herein for all purposes by this reference.

### BACKGROUND OF THE INVENTION

### Field of the Invention

The present invention relates to a system for inducing plasma using harmonic waves and a method of inducing plasma using the same and, more specifically, a plasma induction system and a plasma induction method using the same in which the resonant frequency of an antenna structure for forming an inductively coupled plasma is designed based on a harmonic frequency of a driving frequency of an input voltage.

### Description of the Related Art

Inductively coupled plasma (ICP) is used in various industrial fields such as semiconductors, displays, medical equipment, and spectroscopic analysis technology, as well as environmental energy solutions that reform landfill gas or biogas, by turning gas flowing in the discharge tube into a plasma state by providing radio frequency (RF) energy to an antenna structure surrounding a discharge tube.

In inductively coupled plasma, when the pressure inside the discharge tube is relatively high (e.g., atmospheric pressure), an ignition antenna structure for plasma ignition may be used together with the main antenna structure for maintaining the plasma.

However, when the ignition antenna structure and the main antenna structure are used together, the electromagnetic field formed by any one antenna structure may induce an induced voltage in the other antenna structure, which may cause damage or abnormal operation of the plasma induction system.

Since there has been currently no active research on how to solve the problem of mutual inductive coupling between the above-described antenna structures, this disclosure provides a plasma induction system that effectively solves the above problem.

### SUMMARY OF THE INVENTION

An objective of the present disclosure is to minimize effects of induced voltages resulting from inductive coupling between loads including the antenna structure.

An objective of the present disclosure is to reduce a phase difference between current and voltage applied to loads according to plasma is ignited or maintained for loads having different resonant frequencies.

An objective of the present disclosure is to induce plasma by applying RF voltage to a load for plasma ignition and a load for plasma maintenance using one RF generator.

Objectives of the present disclosure are not limited to the objectives described above, and objectives not mentioned may be clearly understood by a person having ordinary skill in the art to which the present invention pertains from this disclosure and the attached drawings.

According to the embodiment of the present disclosure, an apparatus for inducing plasma comprises: a discharge tube configured to provide a space where the plasma is induced; a first load comprising an ignition antenna structure configured to be disposed to surround the discharge tube and at least one capacitive element configured to be electrically connected in series with the ignition antenna structure; a second load comprising a main antenna structure configured to be disposed to surround the discharge tube and configured to be disposed within a predetermined distance along a direction parallel to a central axis of the discharge tube from the ignition antenna structure, and at least one capacitive element configured to be electrically connected in series with the main antenna structure; and an RF generator configured to apply RF (Radio Frequency) voltage to the first load and the second load; wherein the first load is designed to have an ignition resonant frequency corresponding to (2n+1) times an initial driving frequency that differs from the main resonant frequency by a first value (n is a natural number) when the second load is designed to have a main resonant frequency, and wherein the RF generator is configured to apply RF voltage having the initial driving to the first load and the second load for igniting the plasma.

According to the other embodiment of the present disclosure, a method of inducing plasma for supplying power to an apparatus for inducing plasma, the apparatus comprises: a discharge tube configured to provide a space where the plasma is induced; a first load comprising an ignition antenna structure configured to be disposed to surround the discharge tube and at least one capacitive element configured to be electrically connected in series with the ignition antenna structure; a second load comprising a main antenna structure configured to be disposed to surround the discharge tube and configured to be disposed within a predetermined distance along a direction parallel to the central axis of the discharge tube from the ignition antenna structure, and at least one capacitive element configured to be electrically connected in series with the main antenna structure; and an RF generator configured to apply RF (Radio Frequency) voltage to the first load and the second load; the method comprises: applying an initial RF voltage having the initial driving frequency to the first load and the second load using the RF generator; applying a first RF voltage having a first driving frequency to the first load and the second load after detecting that plasma is ignited in a plasma ignition region corresponding to the ignition antenna structure within the discharge tube, wherein the first driving frequency is determined based on a phase difference of voltage and current applied to the first load, and wherein a magnitude of current flowing in the main antenna structure is increased when the first RF voltage is applied to the second load compared to when the initial RF voltage is applied to the second load; and applying a second RF voltage having a second driving frequency to the first load and the second load after detecting that the ignited plasma is transitioned into a plasma maintenance region corresponding to the main antenna structure within the discharge tube, wherein the second driving frequency is determined based on a phase difference of voltage and current applied to the second load, and wherein a magnitude of the current flowing in the ignition antenna structure is decreased when the second RF voltage is applied to the first load compared to when the first RF voltage is applied to the first load.

The means for solving the problem are not limited to the above-described means, and the means for solving the problem that are not mentioned will be clearly understood by a person having ordinary skill in the art to which the present disclosure pertains from the present disclosure and the attached drawings.

According to an embodiment, even when multiple antenna structures are used for plasma induction, no damage or abnormal operation occurs within the system.

According to an embodiment, a plasma induction system capable of stably igniting and maintaining plasma under atmospheric pressure can be implemented.

According to an embodiment, even when multiple antenna structures are used, the price and volume of the system can be significantly reduced by using a single RF generator.

The effects according to the present disclosure are not limited to the effects described above, and effects that are not mentioned may be clearly understood by those skilled in the art from the present disclosure and the attached drawings.

### BRIEF DESCRIPTION OF THE DRAWINGS

FIG. 1 is a diagram illustrating a plasma induction system according to an embodiment.

FIG. 2 is a diagram illustrating an RF generator according to an embodiment.

FIG. 3 is a diagram illustrating a plasma induction apparatus according to an embodiment.

FIG. 4 is a diagram illustrating a schematic structure of a plasma induction apparatus according to an embodiment.

FIG. 5 is a diagram illustrating the process of operating a plasma induction system according to an embodiment.

FIG. 6 is a diagram illustrating the problem in which an induced voltage is generated depending on the interaction of loads, according to an embodiment.

FIGS. 7A and 7B are a diagram illustrating that the square wave component affecting each load varies depending on the resonant frequency design of the loads, according to an embodiment.

FIG. 8 is a flowchart illustrating a control method of a plasma induction system according to an embodiment.

FIG. 9 is a flowchart illustrating a frequency tracking method for a load according to an embodiment.

FIG. 10 is a flowchart illustrating a harmonic frequency tracking method for a load that has a harmonic frequency as a resonant frequency, according to an embodiment.

FIG. 11 is a flowchart illustrating a frequency tracking method based on power consumption for a load that has a harmonic frequency as a resonant frequency according to an embodiment.

FIG. 12 is a diagram illustrating a frequency tracking method based on power consumption according to an embodiment.

FIG. 13 is a diagram illustrating a plasma induction system using multiple loads and one RF generator according to an embodiment.

FIG. 14 is a flowchart illustrating a process of operating a plasma induction system according to an embodiment.

FIG. 15 and FIG. 16 are diagrams illustrating characteristics of components in a plasma induction system due to plasma induction according to an embodiment.

### DETAILED DESCRIPTION OF THE INVENTION

According to the embodiment of the present disclosure, an apparatus for inducing plasma comprises: a discharge tube configured to provide a space where the plasma is induced; a first load comprising an ignition antenna structure configured to be disposed to surround the discharge tube and at least one capacitive element configured to be electrically connected in series with the ignition antenna structure; a second load comprising a main antenna structure configured to be disposed to surround the discharge tube and configured to be disposed within a predetermined distance along a direction parallel to a central axis of the discharge tube from the ignition antenna structure, and at least one capacitive element configured to be electrically connected in series with the main antenna structure; and an RF generator configured to apply RF (Radio Frequency) voltage to the first load and the second load; wherein the first load is designed to have an ignition resonant frequency corresponding to (2n+1) times an initial driving frequency that differs from the main resonant frequency by a first value (n is a natural number) when the second load is designed to have a main resonant frequency, and wherein the RF generator is configured to apply RF voltage having the initial driving to the first load and the second load for igniting the plasma.

After plasma is ignited in a plasma ignition region corresponding to the ignition antenna structure within the discharge tube, a magnitude of current flowing in the ignition antenna structure is greater when RF voltage having a first driving frequency is applied to the ignition antenna structure compared to when RF voltage having the initial driving frequency is applied to the ignition antenna structure, and the first driving frequency is greater than the initial driving frequency.

The main antenna structure is applied with RF voltage having the same driving frequency as RF voltage applied to the ignition antenna structure, and a magnitude of current flowing in the main antenna structure is greater when RF power with the first driving frequency is applied to the main antenna structure compared to when RF power with the initial driving frequency is applied to the main antenna structure.

After the ignited plasma transitions into a plasma maintenance region corresponding to the main antenna structure within the discharge tube, the magnitude of the current flowing in the main antenna structure is greater when RF power having a second driving frequency is applied to the main antenna structure compared to when RF power having the first driving frequency is applied to the main antenna structure, and the second driving frequency is greater than the first driving frequency.

The ignition antenna structure is applied with RF voltage having driving frequency same as RF voltage applied to the main antenna structure, and The magnitude of the current flowing in the ignition antenna structure is smaller when RF power having the second driving frequency is applied to the ignition antenna structure compared to when RF power having the first driving frequency is applied to the ignition antenna structure.

When the plasma is ignited in a plasma ignition region corresponding to the ignition antenna structure within the discharge tube, the ignited plasma and a first equivalent load comprising the first load have a first equivalent resonant frequency greater than the ignition resonance frequency, and a first difference value obtained by subtracting the initial driving frequency from a value obtained by dividing the first equivalent resonant frequency by (2n+1) corresponds to the first value.

When the ignited plasma transitions into a plasma maintenance region corresponding to the main antenna structure within the discharge tube, the transitioned plasma and a second equivalent load comprising the second load have a second equivalent resonant frequency greater than the main resonant frequency, and a second difference value obtained by subtracting the second equivalent resonant frequency from a value obtained by dividing the first equivalent resonant frequency by (2n+1) is more than or equal to a threshold value.

The threshold value is determined to be more than or equal to 10% of the initial driving frequency.

When the RF generator applies voltage signal having a driving frequency corresponding to the first equivalent resonant frequency to the first load in a state where the plasma is ignited, a difference between a phase of voltage applied to the first load and a phase of current flowing in the first load is 0 or substantially 0.

When the RF generator applies voltage signal having a driving frequency corresponding to the second equivalent resonant frequency to the second load in a state where the plasma is transitioned, a difference between a phase of voltage applied to the second load and a phase of current flowing in the second load is 0 or substantially 0.

When a base driving frequency of voltage signal output by the RF generator is a, a magnitude of the first value is determined within the range of 0.01*a to 0.3*a.

The main resonant frequency has a value between 1.01 times and 1.1 times the initial driving frequency.

The predetermined distance is within 10 cm.

According to the other embodiment of the present disclosure, a method of inducing plasma for supplying power to an apparatus for inducing plasma, the apparatus comprises: a discharge tube configured to provide a space where the plasma is induced; a first load comprising an ignition antenna structure configured to be disposed to surround the discharge tube and at least one capacitive element configured to be electrically connected in series with the ignition antenna structure; a second load comprising a main antenna structure configured to be disposed to surround the discharge tube and configured to be disposed within a predetermined distance along a direction parallel to the central axis of the discharge tube from the ignition antenna structure, and at least one capacitive element configured to be electrically connected in series with the main antenna structure; and an RF generator configured to apply RF (Radio Frequency) voltage to the first load and the second load; the method comprises: applying an initial RF voltage having the initial driving frequency to the first load and the second load using the RF generator; applying a first RF voltage having a first driving frequency to the first load and the second load after detecting that plasma is ignited in a plasma ignition region corresponding to the ignition antenna structure within the discharge tube, wherein the first driving frequency is determined based on a phase difference of voltage and current applied to the first load, and wherein a magnitude of current flowing in the main antenna structure is increased when the first RF voltage is applied to the second load compared to when the initial RF voltage is applied to the second load; and applying a second RF voltage having a second driving frequency to the first load and the second load after detecting that the ignited plasma is transitioned into a plasma maintenance region corresponding to the main antenna structure within the discharge tube, wherein the second driving frequency is determined based on a phase difference of voltage and current applied to the second load, and wherein a magnitude of the current flowing in the ignition antenna structure is decreased when the second RF voltage is applied to the first load compared to when the first RF voltage is applied to the first load.

According to the other embodiment of the present disclosure, an apparatus for inducing plasma, the apparatus comprises: a discharge tube configured to provide a space where the plasma is induced; a first load comprising an ignition antenna structure configured to be disposed to surround the discharge tube and at least one capacitive element configured to be electrically connected in series with the ignition antenna structure; a second load comprising a main antenna structure configured to be disposed to surround the discharge tube and configured to be disposed within a predetermined distance along a direction parallel to the central axis of the discharge tube from the ignition antenna structure, and at least one capacitive element configured to be electrically connected in series with the main antenna structure; and an RF generator configured to apply RF (Radio Frequency) voltage to the first load and the second load, wherein when the second load is designed to have a main resonant frequency, an ignition resonant frequency of the first load is designed to be close to (2n+1) times the main resonant frequency, rather than (2n) times the main resonant frequency or (2n+2) times the main resonant frequency, and wherein n is a natural number.

A method of inducing plasma for supplying power to an apparatus for inducing plasma, the apparatus for inducing plasma comprises: a discharge tube configured to provide a space where the plasma is induced; a first load comprising a first antenna structure configured to be disposed to surround the discharge tube and at least one capacitive element configured to be electrically connected in series with the first antenna structure; and a second load comprising a second antenna structure configured to be disposed to surround the discharge tube and configured to be disposed within a predetermined distance along a direction parallel to the central axis of the discharge tube from the first antenna structure, and at least one capacitive element configured to be electrically connected in series with the second antenna structure; the method of inducing plasma comprises applying a first square wave voltage to the first load at a first time using a first RF generator; and applying a second square wave voltage to the second load at a second time after the first time using a second RF generator; wherein the first square wave voltage has a first driving frequency having a value within a first range set based on a first reference frequency, wherein the second square wave voltage has a second driving frequency having a value within a second range set based on a second reference frequency, wherein the first load is designed to have a first resonant frequency corresponding to (2n+1) times the first reference frequency, wherein the second load is designed to have a second resonant frequency corresponding to the second reference frequency.

The first reference frequency and the second reference frequency are substantially the same.

The method of inducing plasma further comprises calculating a first phase difference for the first load; applying a third square wave voltage to the first load based on the first phase difference, wherein the third square wave voltage has a third driving frequency different from the first driving frequency; calculating a second phase difference for the second load; and applying a fourth square wave voltage to the second load based on the second phase difference, wherein the fourth square wave voltage has a fourth driving frequency different from the second driving frequency.

The calculating the first phase difference comprises: obtaining a first switch signal applied to at least one of switch elements included in the first RF generator, obtaining a first phase signal of current flowing in the first load; generating a first reference signal by processing the first switch signal, wherein frequency of the first reference signal is 2n+1 times frequency of the first switch signal, and calculating the first phase difference using the first reference signal and the first phase signal, Calculating the second phase difference comprises: obtaining a second switch signal applied to at least one of switch elements included in the second RF generator, obtaining a second phase signal of current flowing in the second load, generating a second reference signal corresponding to the second switch signal, and calculating the second phase difference using the second reference signal and the second phase signal.

The generating the first reference signal by processing the first switch signal further comprises time shifting the first switch signal.

The method of inducing plasma further comprises: measuring a first input power of the first RF generator; applying a third square wave voltage to the first load, wherein the third square wave voltage has a third driving frequency different from the first driving frequency; measuring a second input power of the first RF generator; applying a fifth square wave voltage to the first load based on the difference between the first input power and the second input power; calculating a phase difference between voltage and current applied to the second load; and applying a fourth square wave voltage to the second load based on the phase difference, wherein the fourth square wave voltage has a fourth driving frequency different from the second driving frequency.

When the third driving frequency is greater than the first driving frequency and the first input power is less than the second input power, the fifth driving frequency of the fifth square wave voltage has a value greater than the third driving frequency.

When the third driving frequency is greater than the first driving frequency and the first input power is greater than the second input power, the fifth driving frequency of the fifth square wave voltage has a value smaller than the third driving frequency.

Each of the first input power and the second input power is an average value of power measured for the first RF generator during a predetermined time.

The second antenna structure comprises at least one unit antenna and at least one capacitive element.

A system of inducing plasma comprises: a discharge tube configured to provide a space where the plasma is induced; a first load comprising a first antenna structure configured to be disposed to surround the discharge tube and at least one capacitive element configured to be electrically connected in series with the first antenna structure; a second load comprising a second antenna structure configured to be disposed to surround the discharge tube and configured to be disposed within a predetermined distance along a direction parallel to the central axis of the discharge tube from the first antenna structure, and at least one capacitive element configured to be electrically connected in series with the second antenna structure; a first RF (radio frequency) generator configured to be electrically connected to the first load, wherein the first RF generator configured to output a first square wave voltage having a first driving frequency having a value within a first range set based on a first reference frequency; and a second RF generator configured to be electrically connected to the second load, wherein the second RF generator configured to output a second square wave voltage having a second driving frequency having a value within a second range set based on a second reference frequency; wherein the first load is designed to have a first resonant frequency corresponding to (2n+1) times (n is a natural number) of the first reference frequency, wherein the second load is designed to have a second resonant frequency corresponding to the second reference frequency.

The first reference frequency and the second reference frequency are substantially the same.

The second antenna structure of the second load comprises a first to p-th layer antennas and a first to (p−1)-th interlayer capacitive elements, wherein p is a natural number greater than or equal to 2, wherein the first to p-th layer antennas are arranged in different planes, wherein a k-th interlayer capacitive element among the first to (p−1)-th interlayer capacitive elements is electrically interposed between the k-th layer antenna and the (k+1)-th layer antenna.

The first antenna structure of the first load comprises a plurality of layer antennas, wherein no capacitive element is electrically interposed between the plurality of layer antennas.

The system of inducing plasma further comprises a first controller configured to control the first RF generator; wherein the first controller is configured to obtain a first switch signal applied to at least one of switch elements included in the first RF generator, obtain a first phase signal of current flowing in the first load, generate a first reference signal by processing the first switch signal,
calculate the first phase difference using the first reference signal and the first phase signal, apply a third square wave voltage to the first load based on the first phase difference, wherein frequency of the first reference signal is 2n+1 times frequency of the first switch signal.

The system of inducing plasma further comprises a first controller configured to control the first RF generator; wherein the first controller is configured to: measure a first input power of the first RF generator, apply a third square wave voltage having a third driving frequency different from the first driving frequency to the first load, measure a second input power of the first RF generator, apply a fifth square wave voltage to the first load based on a difference between the first input power and the second input power.

When the third driving frequency is greater than the first driving frequency and the first input power is less than the second input power, the fifth driving frequency of the fifth square wave voltage has a value greater than the third driving frequency.

When the third driving frequency is greater than the first driving frequency and the first input power is greater than the second input power, the fifth driving frequency of the fifth square wave voltage has a value less than the third driving frequency.

The first input power and the second input power are each an average value of power measured for the first RF generator during a predetermined time.

The above-described objectives, features, and advantages of the present disclosure will become more apparent through the following detailed description with reference to the attached drawings. Since the present disclosure may have various modifications and various embodiments, specific embodiments will be illustrated in the drawings and described in detail hereinafter.

In the drawings, the thicknesses of layers and regions are exaggerated for clarity. In addition, when an element or layer is referred to as “on” another element or layer, it includes not only the case where the element or layer is directly above the other element or layer, but also the case where another element or layer is interposed in between. Throughout the specification, the same reference numerals represent, in principle, the same components. In addition, components that have the same function within the scope of the same idea shown in the drawings of each embodiment are described using the same reference numerals, and redundant descriptions thereof are omitted.

The numbers (e.g., first, second, etc.) used in the description of the present disclosure are merely identifiers for distinguishing one component from another.

In addition, the suffixes “module” and “part” used for components in the following examples are given or used interchangeably only for the convenience of writing the specification, and do not have distinct meanings or roles in themselves.

In the following examples, singular expressions include plural expressions unless the context clearly indicates otherwise.

In the following examples, terms such as “include” or “have” mean that a feature or component described in the specification is present, and do not preclude the possibility that one or more other features or components may be added.

In the drawings, the sizes of components may be exaggerated or reduced for convenience of explanation. For example, the sizes and thicknesses of each component shown in the drawings are arbitrarily shown for convenience of explanation, and the present invention is not necessarily limited to what is shown.

In cases where some embodiments may be implemented differently, a specific process order may be performed differently from the order described. For example, two processes described in succession may be performed substantially simultaneously, or may be performed in an order opposite to the order described.

Unless specifically stated or clear from context, it will be appreciated that the term “about” in relation to a numerical value may be understood to mean the numerical value mentioned and up to +/−10% of that numerical value. It will be appreciated that the term “about” in relation to a numerical range may be understood to mean a range from a value 10% less than the lower limit of the numerical range to a value 10% greater than the upper limit of the numerical range.

In the following examples, when films, regions, components, etc. are said to be connected, it includes not only cases where the films, regions, or components are directly connected, but also cases where another films, regions, or components are interposed in between so that they are indirectly connected each other.

For example, in the present disclosure, the meaning that films, regions, components, etc. are electrically connected includes not only cases where the films, regions, components, etc. are physically connected or integrally formed to allow the flow to move so that they are directly electrically connected, but also cases where another films, regions, components, etc. are intervened in between so that they are indirectly electrically connected.

In addition, for example, in the present disclosure, the meaning that films, regions, components, etc. are fluidly connected includes not only cases where the films, regions, components, etc. are physically connected or integrally formed so that they are directly fluidly connected to allow the fluid to move, but also cases where another films, regions, components, etc. are intervened in between so that they are indirectly fluidly connected.

The present disclosure relates to a system for inducing plasma using harmonic waves and a plasma induction method using the same. More specifically, it relates a plasma induction system that has improved stability and durability and also reduced price and volume, and a control protocol for driving the same.

The plasma induction system and a method of using the same described in the present disclosure may be used in a plasma process. Here, the plasma process refers to a process for generating plasma and using the generated plasma, which is used in semiconductor processes, display processes, nano processes, gas reforming processes, etc.

As a plasma induction method in the plasma induction system herein, an inductively coupled plasma (ICP) is used, which refers to a method of forming an electromagnetic field inside the discharge tube by applying radio frequency (RF) voltage to a load including an antenna structure, thereby turning gas inside the discharge tube into a plasma state. Herein, the antenna structure refers to an object that includes a coil or an antenna and receives power to form an induced electric field or a capacitive electric field for generating plasma, and may be designed in various ways depending on the purpose and specifications of the plasma induction system.

Meanwhile, it is to be noted in advance that the technical idea of the present disclosure is not limited to an inductively coupled plasma among plasma induction methods, but is applied to a method of inducing plasma using RF voltage, particularly a RF voltage of square wave, for example, a capacitively coupled plasma (CCP).

The use of harmonics herein means utilizing not only the components having a fundamental frequency, but also harmonic components that are multiples of the fundamental frequency, among components that create non-sinusoidal waves such as square waves or pulse waves.

### 1. Plasma Induction System

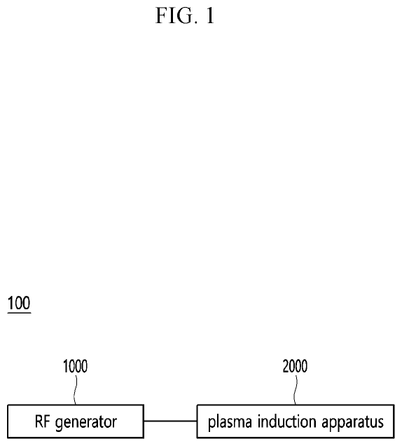

Hereinafter, the plasma induction system 100 will be described with reference to FIG. 1.

FIG. 1 is a diagram illustrating a plasma induction system 100 according to an embodiment.

Referring to FIG. 1, the plasma induction system 100 may include an RF generator 1000 and a plasma induction apparatus 2000.

The RF generator 1000 may provide power to the plasma induction apparatus 2000. For example, the RF generator 1000 may apply AC power having a specific driving frequency to a load of the plasma induction apparatus 2000. Here, the AC power may mean AC voltage or AC current, and it will be referred to as “RF voltage” below for the convenience of explanation.

The RF voltage provided by the RF generator 1000 may be understood as a non-sinusoidal wave having a specific frequency. For example, the RF voltage may be a square wave having a specific driving frequency and a specific size.

The RF generator 1000 may be designed to have a specific performance. Specifically, the driving frequency of the RF voltage provided by the RF generator 1000 may have a specific range, and the power provided by the RF generator 1000 may also have a specific range. For example, the RF generator 1000 may have a driving frequency of about 0.2 MHz to about 60 MHz and a power of about 100 W to about 50 kW.

In the plasma induction process, the RF generator 1000 may change the driving frequency of the RF voltage in real time when applying RF voltage to the plasma induction apparatus 2000. More specifically, the RF generator 1000 may configure the driving frequency of the RF voltage applied to the load to a value close to the resonant frequency of the load so that the current flowing in the load in the plasma induction apparatus 2000 approaches the maximum value. Here, as the plasma is induced, a magnitude of the current flowing in the load is affected by the resonant frequency of the composite component of the load and the plasma, and the RF generator 1000 may adjust the driving frequency so that it approaches the resonant frequency of the composite component. Hereinafter, for the convenience of explanation, such a method of adjusting the driving frequency is referred to as frequency tracking, and the frequency tracking operation will be described later.

The RF generator 1000 may control the power consumed in the plasma induction system 100. For example, the RF generator 1000 may perform an operation of applying RF voltage and an operation of not applying RF voltage, and control the power consumed in the plasma induction system 100 within a specific range by increasing the number of times the operation of not applying RF voltage is performed within a unit time duration.

The plasma induction apparatus 2000 may receive RF voltage to induce plasma. For example, the plasma induction apparatus 2000 includes a discharge tube and loads as described below, in which the loads may receive RF voltage and form an electromagnetic field for plasma induction inside the discharge tube, and the gas introduced inside the discharge tube may transition to a plasma state by the electromagnetic field.

The plasma induction apparatus 2000 may be designed in various ways depending on conditions of the environment in which it is used. Here, the conditions of the environment in which it is used refer to the purpose (e.g., pressure inside the discharge tube), performance (e.g., energy conversion efficiency, standard power consumption), volume, and price of the plasma induction system 100.

The RF generator 1000 and the plasma induction apparatus 2000 may be provided as the plasma induction system 100. However, the RF generator 1000 and the plasma induction apparatus 2000 may each be provided as a single product, and the plasma induction apparatus 2000 may also be provided with the discharge tube and the load being separate products.

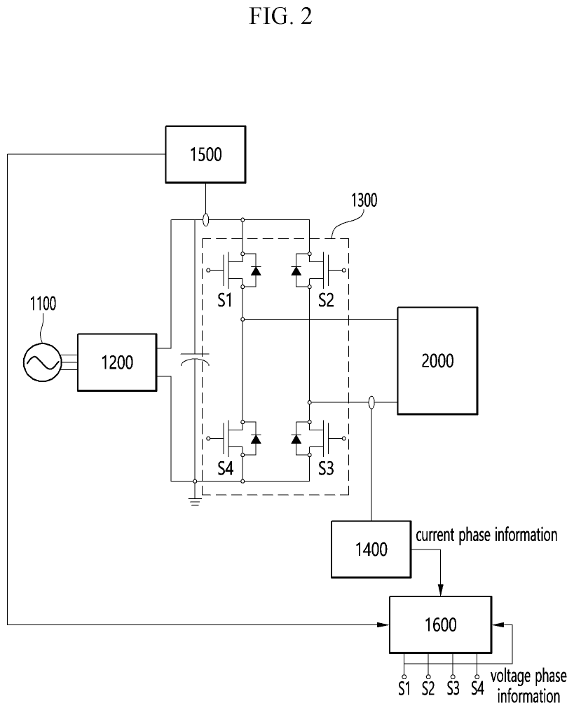

Hereinafter, the RF generator 1000 and the plasma induction apparatus 2000 will be described in more detail with reference to FIGS. 2 to 4.

### 1.1 RF Generator

FIG. 2 is a diagram illustrating an RF generator 1000 according to an embodiment.

Referring to FIG. 2, the RF generator 1000 may include an AC power supply 1100, a rectifier 1200, an inverter 1300, a phase sensing module 1400, a power sensing module 1500, and a control unit 1600.

The AC power supply 1100 is configured to provide AC power used in the RF generator 1000. The RF generator 1000 may be supplied with AC power from an AC power supply commonly used in homes or industries, in which the RF generator 1000 may receive AC power from an external power supply without including the AC power supply 1100.

The RF generator 1000 may receive AC power from the AC power supply 1100 and supply an RF voltage having a specific driving frequency to the plasma induction apparatus 2000.

The rectifier 1200 may convert the output of the AC power supply 1100 into a DC voltage.

The rectifier 1200 may convert the AC voltage supplied from the AC power supply 1100 into a DC voltage and apply it to the input terminals of the inverter 1300. The rectifier 1200 may be implemented as a circuit including a plurality of diodes.

The inverter 1300 may receive a DC voltage from the rectifier 1200 and supply an RF voltage to the plasma induction apparatus 2000. For example, the inverter 1300 may receive a switch signal and provide an RF voltage to the load of the plasma induction apparatus 2000 using the received switch signal. Here, the switch signal may be understood as a signal corresponding to a pulse width modulation (PWM) signal generated by the control unit 1600 as described below, and the PWM signal may be understood as a signal that determines the driving frequency of the voltage signal.

The inverter 1300 may include at least one switching element controlled by a switching signal, and the RF voltage supplied from the inverter 1300 to the load may have the driving frequency configured based on the switching signal provided to the inverter 1300.

For example, the inverter 1300 may be implemented in a full bridge form. Specifically, the inverter 1300 may include first to fourth switches S1, S2, S3, and S4. Here, the first to fourth switches S1, S2, S3, and S4 may receive a switch signal and maintain an on state or an off state. Herein, when the first and third switches S1 and S3 are maintained in an on state and the second and fourth switches S2 and S4 are maintained in an off state, a positive voltage is output through an output terminal of the inverter 1300; and when the first and third switches S1 and S3 are maintained in an off state and the second and fourth switches S2 and S4 are maintained in an on state, a negative voltage may be output through the output terminal of the inverter 1300. In this way, the inverter 1300 may alternately output positive and negative voltages through the output terminals to supply an RF voltage having a specific frequency.

Herein, the voltage output through the output terminals of the inverter 1300 may be in the form of a square wave or a pulse wave. This is because the voltage output through the inverter 1300 is maintained at a positive constant value or a negative constant value as the DC voltage is output in the positive or negative direction from the inverter 1300, as described above.

The implementation method of the inverter 1300 is not limited to the form described above, and it may be understood that the inverter 1300 is an example of a power conversion device that performs the function of converting a DC voltage into an AC voltage.

The inverter 1300 may be controlled, for example, in a time delay method, a pulse width modulation (PWM) method, or a combination thereof, according to a frequency control method of the control unit 1600.

Meanwhile, a capacitive element may be disposed between the rectifier 1200 and the inverter 1300. For example, the RF generator 1000 includes a capacitor connected in parallel to the input terminals of the inverter 1300. This capacitive element may be understood as a filter that causes the voltage input to the inverter 1300 to be in a form close to a direct current form.

The control unit 1600 may generate a PWM signal corresponding to the driving frequency. Specifically, the control unit 1600 may receive data sensed from the phase sensing module 1400 and/or the power sensing module 1500 described below to generate the PWM signal described above. For example, the control unit 1600 may obtain phase difference data or delay time by using phase data of the current applied to the load and phase data of the voltage applied to the load, which obtained from the phase sensing module 1400, and generate a PWM signal based on this. Herein, the PWM signal previously output may be used as the phase data of the voltage applied to the load.

The control unit 1600 may be implemented as a device such as a central processing unit (CPU), a microprocessor, a processor core, a multiprocessor, an application-specific integrated circuit (ASIC), or a field programmable gate array (FPGA) depending on hardware, software, or a combination thereof. In addition, the control unit 1600 may be divided into multiple modules, rather than one module. For example, the control unit 1600 may be composed of a phase difference calculation module that calculates a phase difference and a signal output module that outputs a PWM signal.

The phase sensing module 1400 may detect electrical characteristics of the load, such as the size or phase of the current applied to the load, and provide data related thereto to the control unit 1600.

Although not shown in FIG. 2, the phase sensing module 1400 may include a current transformer, a filter, and a comparator.

The phase sensing module 1400 receives a current or voltage signal flowing through the load through a current transformer to convert it into a current or voltage signal of different size, filters the converted current or voltage signal using a filter, and provides phase data to the control unit 1600 through a comparator.

The current transformer may be inductively coupled to the wiring between the inverter 1300 and the load and may convert the voltage or current signal applied to the load to provide it to the filter. Specifically, the current transformer may convert a current flowing in a conductor connected to the load into a voltage signal.

The filter may remove a DC component from the input current or voltage signal and output it to the comparator. To this end, the filter may perform high pass filtering or low pass filtering.

The comparator may obtain phase data. For example, the comparator may obtain the phase data by comparing the voltage signal obtained from the current transformer or filter with a predetermined value. Herein, the phase data may mean phase data of the current applied to the load.

At least one of the above-described configurations included in the phase sensing module 1400 may be omitted, and the phase sensing module 1400 may be implemented in a different manner. In addition, the phase sensing module 1400 may include a voltage sensor for measuring the voltage of the load to measure the magnitude or phase of the voltage applied to the load.

As described above, the RF generator 1000 may control the driving frequency of the RF voltage provided to the load based on data regarding the resonant frequency of the load. In other words, the RF generator 1000 may monitor a phase difference between current and voltage applied to the load according to plasma generation, and adjust the driving frequency of the RF voltage to reduce the phase difference.

The power sensing module 1500 may collect data for calculating power consumed by the inverter 1300 and the load. For example, the power sensing module 1500 may measure current and/or voltage applied to the inverter 1300 and provide data related thereto to the control unit 1600. To this end, the power sensing module 1500 may be installed at the input terminal of the inverter 1300.

The power sensing module 1500 may be divided into a voltage sensor for measuring voltage and a current sensor for measuring current. Here, the current sensor may be implemented in the same manner as the phase sensing module 1400 described above. In addition, a resistance-type sensor or a capacitor-type sensor may be used as the voltage sensor.

Meanwhile, the power sensing module 1500 may also collect data for calculating power consumed by the load. For example, the power sensing module 1500 may measure current and/or voltage applied to the load and provide data related thereto to the control unit 1600. To this end, the power sensing module 1500 may be installed at the output terminal of the inverter 1300 or the input terminal of the load.

The control unit 1600 may calculate the average power consumed by the inverter 1300 and the load based on the data obtained from the power sensing module 1500, and may adjust the average power supplied to the inverter 1300 and the load by comparing the calculated average power consumption with the predetermined reference power consumption.

Meanwhile, although not shown in FIG. 2, the RF generator 1000 may include a memory. The memory may store various data such as values measured by the phase sensing module 1400 or the power sensing module 1500 or programs such as control protocols executed by the control unit 1600. Examples of the memory may include a hard disk drive (HDD), a solid state drive (SSD), a flash memory, a read-only memory (ROM), a random access memory (RAM), etc. The memory may be provided in a form built into the RF generator 1000 or in a detachable form.

In addition, the RF generator 1000 may include an input unit for receiving input from a user. The input unit may receive user input from a user. The user input may be in various forms, including key input, touch input, and voice input. The input unit is a comprehensive concept that includes a keypad, keyboard, and mouse of conventional forms, a touch sensor that detects the user's touch, and input means of various forms that detect or receive various forms of user input.

In addition, the RF generator 1000 may include an output unit for providing information to the user. The output unit may output information (e.g., phase difference of voltage applied to the load and current flowing, power consumed by the inverter 1300 and the load, driving frequency of the RF generator 1000, temperature of the plasma induction apparatus 2000, etc.) about the status of the plasma induction system 100 and provide it to the user. The output unit is a comprehensive concept that includes a display that outputs images, a speaker that outputs sounds, a haptic device that generates vibrations, and various other forms of output means.

The RF generator 1000 described above may have at least one of its components omitted. For example, the RF generator 1000 may obtain electrical data about a load or an inverter 1300 from an external sensor without including the phase sensing module 1400 and/or the power sensing module 1500. As another example, the RF generator 1000 may receive a DC voltage or a rectified DC voltage from an external source without including the AC power supply 1100 and the rectifier 1200.

The plasma induction system 100 may include multiple RF generators 1000. For example, the plasma induction system 100 may include as many RF generators 1000 as the number of loads included in the plasma induction apparatus 2000. Herein, each RF generator 1000 may apply an RF voltage to each antenna structure.

For example, the plasma induction apparatus 2000 may include a first load and a second load, each including an antenna structure, and the plasma induction system 100 may include a first RF generator for applying the RF voltage to the first load and a second RF generator for applying the RF voltage to the second load. The first RF generator and the second RF generator may receive an AC voltage from the same AC power supply and provide the RF voltage to the first load and the second load, respectively.

In the case where there are multiple RF generators 1000, the plasma induction system 100 may further include a system control unit for controlling the multiple RF generators 1000. The system control unit may control each of the multiple RF generators 1000 based on data acquired through each RF generator 1000.

Meanwhile, even when multiple loads are included in the plasma induction apparatus 2000, the plasma induction system 100 may include one RF generator 1000. For example, the first load and the second load included in the plasma induction apparatus 2000 may be connected in parallel to the output terminals of the RF generator 1000 to receive RF voltage.

### 1.2 Plasma Induction Apparatus

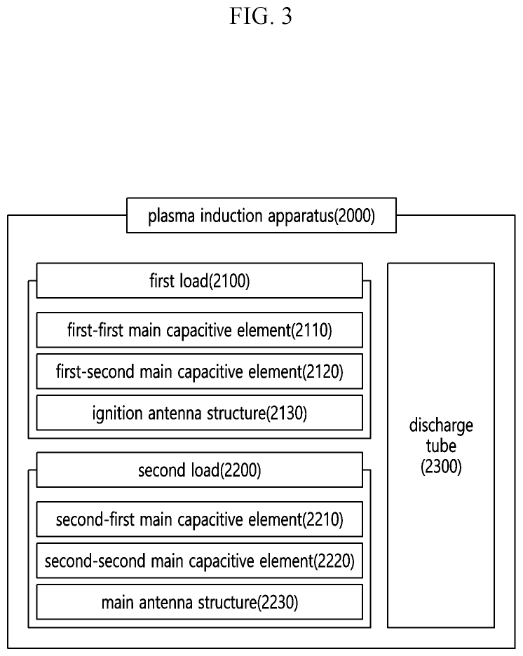

FIG. 3 is a diagram illustrating a plasma induction apparatus 2000 according to an embodiment.

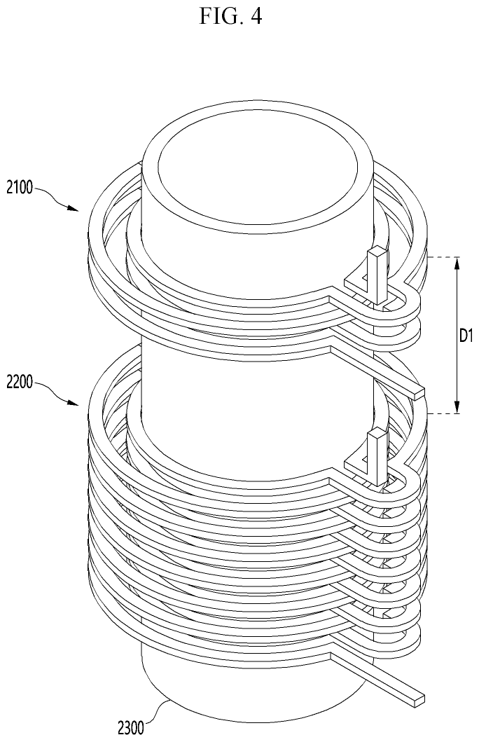

FIG. 4 is a diagram showing a schematic structure of a plasma induction apparatus 2000 according to an embodiment.

Referring to FIG. 3, the plasma induction apparatus 2000 may include a first load 2100, a second load 2200, and a discharge tube 2300. The first load 2100 is configured to ignite plasma, the second load 2200 is configured to maintain plasma, and the discharge tube 2300 is configured to provide a space where plasma is ignited and maintained.

The discharge tube 2300 includes a gas inlet portion into which gas is introduced, an inner wall defining a plasma induction region, and a discharge portion to which reformed gas is discharged.

The discharge tube 2300 may have various shapes, such as a cylindrical shape or a polygonal cylindrical shape, and at least a portion of the discharge tube 2300 may be made of at least one material of aluminum oxide, silicon nitride, silicon nitride, silicon dioxide, yttrium oxide, ceramic, silicon carbide, or a combination thereof, which are resistant to heat.

The first load 2100 may include a first-first main capacitive element 2110, a first-second main capacitive element 2120, and an ignition antenna structure 2130.

The ignition antenna structure 2130 may be disposed to around the discharge tube 2300. The ignition antenna structure 2130 may be implemented in a coil-like shape or ring shape that make it possible to surround the outer surface of the discharge tube 2300.

The ignition antenna structure 2130 may have a layered structure. The ignition antenna structure 2130 may have a structure in which identical or similar structures are stacked in the length direction of the discharge tube 2300. For example, as illustrated in FIG. 4, the ignition antenna structure 2130 may have a two-layer structure including two antenna layers. The number of layers of the ignition antenna structure 2130 is not limited to two and may be appropriately determined as needed.

One layer of the ignition antenna structure 2130 may be composed of multiple turns. For example, as illustrated in FIG. 4, the ignition antenna structure 2130 may be composed of two antenna turns, that is, an inner antenna turn that surround the outer surface of the discharge tube 2300 and an outer antenna turn that surround the inner antenna turn. The number of turns constituting each layer of the ignition antenna structure 2130 is not limited to two and may be appropriately determined as needed.

The ignition antenna structure 2130 includes N layer antennas (N is a natural number), and each of the N layer antennas may have M turns (M is a natural number).

The first-first main capacitive element 2110 may be electrically connected to one end of the ignition antenna structure 2130, and the first-second main capacitive element 2120 may be electrically connected to the other end of the ignition antenna structure 2130. Therefore, the ignition antenna structure 2130 may be electrically connected to one end of the inverter 1300 of the RF generator 1000 through the first-first main capacitive element 2110, and may be electrically connected to the other end of the inverter 1300 of the RF generator 1000 through the first-second main capacitive element 2120.

The first-first main capacitive element 2110 and the first-second main capacitive element 2120 may be implemented as capacitive elements or equivalent circuits thereof which have a function of storing electric energy, such as a capacitor, a multilayer ceramic capacitor, an ultracapacitor, etc.

Meanwhile, any one of the first-first main capacitive element 2110 and the first-second main capacitive element 2120 may be omitted.

The ignition resonance frequency (or first resonance frequency) of the first load 2100 may be determined based on the capacitance of the first-first main capacitive element 2110, the capacitance of the first-second main capacitive element 2120, and the inductance of the ignition antenna structure 2130. In other words, when a value of the ignition resonance frequency of the first load 2100 is determined, the capacitance of the first-first main capacitive element 2110, the capacitance of the first-second main capacitive element 2120, and the inductance of the ignition antenna structure 2130 may be designed based on the value.

The second load 2200 may include a second-first main capacitive element 2210, a second-second main capacitive element 2220, and a main antenna structure 2230.

The main antenna structure 2230 may be disposed to around the discharge tube 2300. The main antenna structure 2230 may be implemented in a coil-like shape or ring shape that makes it possible to surround the outer surface of the discharge tube 2300.

The main antenna structure 2230 may have a layered structure. The main antenna structure 2230 may have a structure in which identical or similar structures are laminated in the length direction of the discharge tube 2300. For example, as illustrated in FIG. 4, the main antenna structure 2230 may have a seven-layer structure including seven antenna layers. The number of layers of the main antenna structure 2230 is not limited to seven layers and may be appropriately determined as needed.

One layer of the main antenna structure 2230 may be composed of multiple turns. For example, as illustrated in FIG. 4, the main antenna structure 2230 may be composed of two antenna turns, i.e., an inner antenna turn that surround the outer surface of the discharge tube 2300 and an outer antenna turn that surround the inner turn antenna. The number of turns constituting each layer of the main antenna structure 2230 is not limited to two and may be appropriately determined as needed.

The main antenna structure 2230 may include at least one capacitive element. For example, a capacitive element may be electrically interposed between a plurality of antennas constituting the main antenna structure 2230. Specifically, an interlayer capacitive element may be electrically interposed between layer antennas included in the main antenna structure 2230. Alternatively, an interturn capacitive element may be electrically interposed between antenna turns constituting the layer antennas included in the main antenna structure 2230.

Here, the interlayer capacitive element or the interturn capacitive element may be implemented as a capacitive element or its equivalent circuit which have a function of storing electric energy, such as condenser, capacitors, multilayer ceramic capacitors, ultracapacitors, etc. The main antenna structure 2230 includes N layer antennas (N is a natural number), and each of the N layer antennas may include M turn antennas (M is a natural number). The main antenna structure 2230 includes N−1 interlayer capacitive elements, and the P-th interlayer capacitive element among the N−1 interlayer capacitive elements may be electrically interposed between the P-th layer antenna and the P+1-th layer antenna among the N layer antennas. Alternatively, the main antenna structure 2230 includes M−1 inter-turn capacitive elements, and the Q-th inter-turn capacitive element among the M−1 interturn capacitive elements may be electrically interposed between the Q-th antenna turn and the Q+1-th antenna turn among the M antenna turns.

Meanwhile, the layer antenna included in the main antenna structure 2230 may be composed of multiple unit antennas. For example, the layer antenna may be composed of A unit antennas (A is a natural number greater than or equal to 2), in which each unit antenna may be composed of a first arc portion including a first end and a second end and having a first radius of curvature, a second arc portion including a third end and a fourth end and having a second radius of curvature different from the first radius of curvature, and an arc connection portion connecting the second end of the first arc portion and the third end of the second arc portion. Herein, B-th unit antennas and B+1-th unit antennas that are adjacent to each other (B is a natural number smaller than A) may be disposed so that the angle formed by the intersection of the virtual first line connecting the center of the main antenna structure 2230 (or the center of the discharge tube 2300) and the arc connection part of the B unit antenna and the virtual second line connecting the center of the main antenna structure 2230 and the arc connection part of the B+1 unit antenna is 360/A degrees.

The number of layer antennas included in the ignition antenna structure 2130 may be different from the number of layer antennas included in the main antenna structure 2230, and the number of turns of the layer antennas included in the ignition antenna structure 2130 may be different from the number of turns of the layer antennas included in the main antenna structure 2230.

Unlike the main antenna structure 2230, the ignition antenna structure 2130 may not include a capacitive element. This is because when a capacitive element is included in the antenna structure, the voltage applied to both ends of the antenna structure is relatively low, and as described later, a relatively high voltage must be applied to the ignition antenna structure 2130 during the plasma induction process. Of course, the ignition antenna structure 2130 may include a capacitive element, and the main antenna structure 2230 may not include a capacitive element.

The second-first main capacitive element 2210 may be electrically connected to one end of the main antenna structure 2230, and the second-second main capacitive element 2220 may be electrically connected to the other end of the main antenna structure 2230. Therefore, the main antenna structure 2230 may be electrically connected to one end of the inverter 1300 of the RF generator 1000 through the second-first main capacitive element 2210, and may be electrically connected to the other end of the inverter 1300 of the RF generator 1000 through the second-first main capacitive element 2210.

The second-first main capacitive element 2210 and the second-second main capacitive element 2220 may be implemented as a capacitive element or an equivalent circuit thereof which have a function of storing electric energy, such as condenser, a capacitor, a multilayer ceramic capacitor, an ultracapacitor.

Meanwhile, either of the second-first main capacitive element 2210 and the second-second main capacitive element 2220 may be omitted.

A main resonant frequency (or second resonant frequency) of the second load 2200 may be determined based on the electrostatic capacitance of the second-first main capacitive element 2210, the electrostatic capacitance of the second-second main capacitive element 2220, and the inductive capacitance of the main antenna structure 2230. In other words, when a value of the main resonant frequency of the second load 2200 is determined, the electrostatic capacitance of the second-first main capacitive element 2210, the electrostatic capacitance of the second-second main capacitive element 2220, and the inductive capacitance of the main antenna structure 2230 may be designed based on the value.

The ignition antenna structure 2130 of the first load 2100 and the main antenna structure 2230 of the second load 2200 may be disposed to around the discharge tube 3000 at a predetermined distance apart from each other. For example, as illustrated in FIG. 4, the main antenna structure 2230 may be disposed at a first distance (D1) apart from the ignition antenna structure 2130 in the longitudinal direction of the discharge tube 2300.

Herein, as described later, in order for the plasma ignited in an area adjacent to the ignition antenna structure 2130 to be transitioned to an area adjacent to the main antenna structure 2230, the distance between the ignition antenna structure 2130 and the main antenna structure 2230 needs to be within a certain distance. The first distance D1 may be determined by the diameter of the discharge tube 3000, the amount of power used, the type of gas supplied to the discharge tube 3000, the driving frequency of the RF generator 1000, the gas supply flow rate, the structure of the nozzle supplying the gas, etc. For example, when the diameter of the discharge tube 3000 is about 5 cm to about 20 cm, the amount of power used is about 10 kW to about 50 kW, and the driving frequency of the RF generator 1000 is about 2 MHz to about 4 MHz, the first distance D1 may be about 5 cm or less.

Meanwhile, when the ignition antenna structure 2130 and the main antenna structure 2230 is designed to be relatively close to each other, mutual induction results in causing one antenna structure to affect the other antenna structure, which may hinder the stability of the plasma induction system 100 and cause abnormal operation, as described below.

### 1.4 Plasma Induction Process

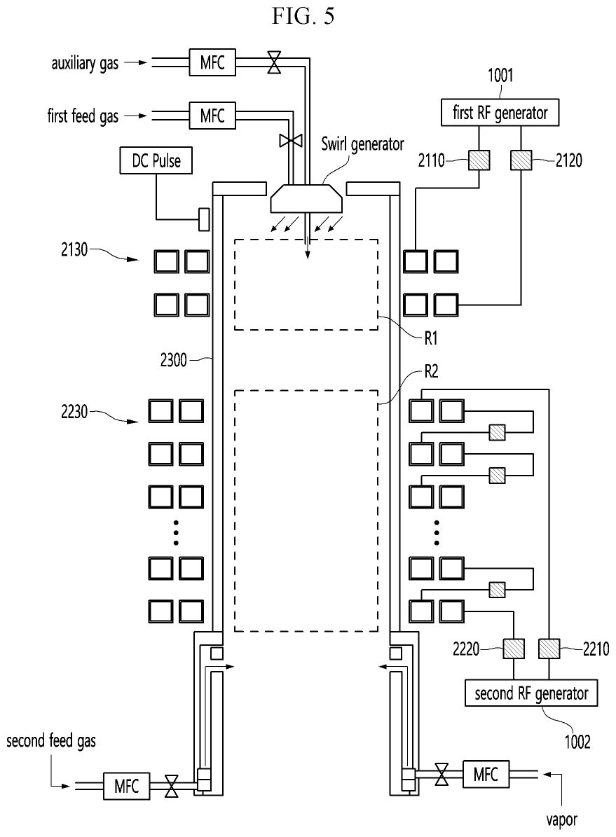

Hereinafter, the process of operating the plasma induction system 100 will be described with reference to FIG. 5.

FIG. 5 is a diagram illustrating the process of operating the plasma induction system 100 according to an embodiment. FIG. 5 shows a cross-section of the plasma induction apparatus 2000. Although FIG. 5 exemplarily describes a case where the plasma induction system 100 is used in a gas reforming process, the technical idea of the present disclosure is not limited thereto, and may be applied in the same manner when the plasma induction system 100 is used in another process utilizing plasma.

Referring to FIG. 5, the plasma induction system 100 includes a first RF generator 1001 and a second RF generator 1002, and each RF generator is configured to apply RF voltage to a first load 2100 and a second load 2200 of the plasma induction apparatus 2000.

A plasma induction region within the discharge tube 2300 may be divided into a first region R1 and a second region R2.

The first region R1 is a region corresponding to the ignition antenna structure 2130 in the inner space of the discharge tube 2300. The ignition antenna structure 2130 receives RF voltage from the first RF generator 1001 to form an electromagnetic field in the first region R1, and the auxiliary gas introduced into the first region R1 may move and collide with each other by the formed electromagnetic field to transition to a plasma state. In other words, the first region R1 may be understood as a region where plasma is ignited and generated.

The second region R2 is a region corresponding to the main antenna structure 2230 in the inner space of the discharge tube 2300. The main antenna structure 2230 receives an RF voltage from the second RF generator 1002 to form an electromagnetic field in the second region R2, and the plasma ignited in the first region R1 by the formed electromagnetic field may transition to the second region R2 and be maintained. In a state where the plasma is maintained in the second region R2, a gas to be reformed (e.g., first feed gas, second feed gas, water vapor) is introduced and reformed by the plasma, thereby generating a synthetic gas. The second region R2 may be understood as a region where the ignited plasma moves and is maintained and gas reforming is performed.

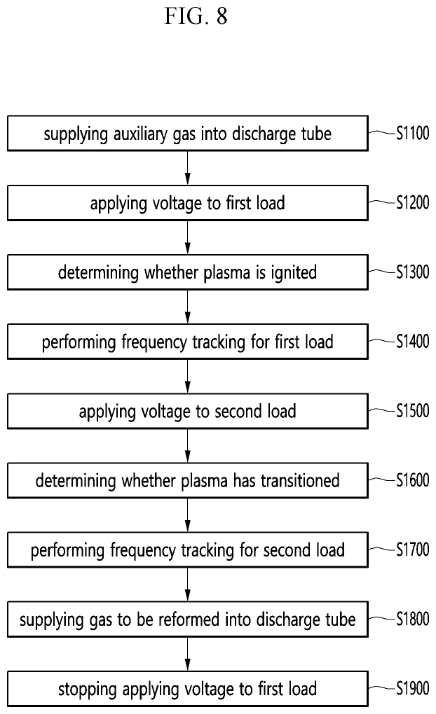

The specific method of controlling the plasma induction system 100 for the gas reforming process will be described later with reference to FIG. 8.

### 1.5 Problems in Plasma Induction

As described above, in the process of igniting and maintaining the plasma, RF voltage is applied to the ignition antenna structure 2130 and the main antenna structure 2230. Herein, since the ignition antenna structure 2130 and the main antenna structure 2230 is relatively close to each other, the ignition antenna structure 2130 and the main antenna structure 2230 may interact each other, which results in problems.

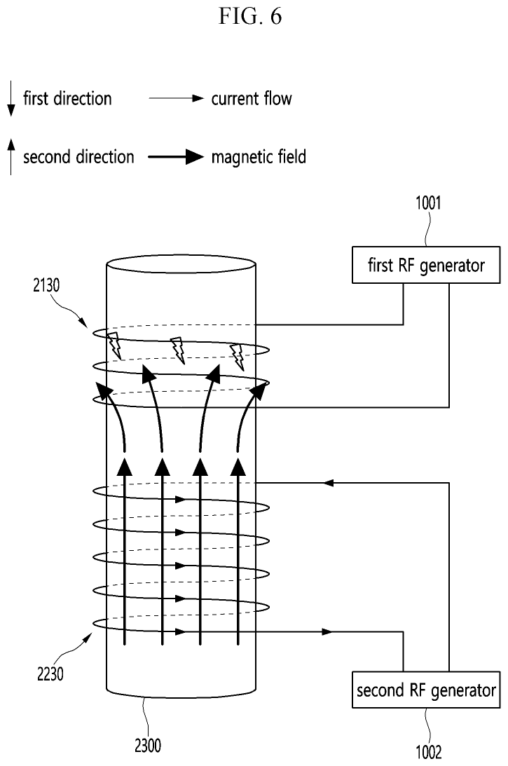

FIG. 6 is a diagram illustrating a problem in which an induced voltage is generated according to the interaction of loads according to an embodiment. It is to be noted that FIG. 6 is a diagram schematically illustrating a plasma induction system 100 for the convenience of explanation.

In the plasma maintenance process described in FIG. 5, when RF voltage is applied to the main antenna structure 2230 by the second RF generator 1002, RF current flows in the main antenna structure 2230, which results that a magnetic field may be formed. For example, as shown in FIG. 6, as viewed from the first direction, when current flows counterclockwise in the main antenna structure 2230, a magnetic field may be formed around the second direction (Ampere's circuit law). As another example, as viewed from the first direction, when current flows clockwise in the main antenna structure 2230, a magnetic field may be formed around the first direction, which is the opposite direction to the second direction.

Here, the first direction refers to a direction from the ignition antenna structure 2130 to the main antenna structure 2230 among directions parallel to the central axis of the discharge tube 2300, a direction in which the ignited plasma moves, or a direction in which the auxiliary gas is introduced. The second direction means a direction opposite to the first direction.

The magnetic field formed by the main antenna structure 2230 causes a change in the magnetic field in the area where the ignition antenna structure 2130 is located, whereby an induced electromotive force is generated in the ignition antenna structure 2130.

Due to the induced electromotive force generated in the ignition antenna structure 2130, RF current flows in the ignition antenna structure 2130, whereby an electromagnetic field is formed in the first region R1 in the discharge tube 2300 so that an abnormal operation occurs in which plasma in a steady state in the second region R2 moves to the first region R1. In addition, as the induced electromotive force is generated in the ignition antenna structure 2130, voltage stress may occur in the first RF generator 1001 electrically connected to the ignition antenna structure 2130, which may cause damage in the first RF generator 1001.

In addition, the induced electromotive force generated in the main antenna structure 2230 by the magnetic field formed by the ignition antenna structure 2130 may generate voltage stress in the second RF generator 1002 electrically connected to the main antenna structure 2230, which may cause damage.

The above-described problem is more likely to occur, especially when the ignition resonance frequency of the first load 2100 is similar to the main resonant frequency of the second load 2200. Specifically, since the frequency of the current flowing in the second load 2200 by controlling frequency tracking is controlled to be similar to the main resonant frequency of the second load 2200, and the frequency of the induced electromotive force by the main antenna structure 2230 is similar to the frequency of the current flowing in the second load 2200, as described below, the frequency of the induced electromotive force generated in the first load 2100 also becomes similar to the main resonant frequency of the second load 2200. Herein, when the ignition resonance frequency and the main resonant frequency of the first load 2100 are similar to each other, the first load 2100 resonates due to the induced electromotive force, causing a larger current to flow.

Therefore, in order to solve this problem, it is necessary to configure the ignition resonant frequency of the first load 2100 and the main resonant frequency of the second load 2200 differently.

As the higher the resonant frequency of each load is designed, the greater the electric energy supplied to the plasma may be, which is directly relate to the improvement of plasma ignition or maintenance efficiency, designing the resonant frequency of one load less than the resonant frequency of the other load results in lowering the efficiency of either plasma ignition or maintenance, thereby lowering the efficiency of the plasma induction system 100.

As a result, a method is required to minimize the influence of the interaction between the first load 2100 and the second load 2200 while maintaining the efficiency of the plasma induction system 100.

### 2. Design Plan for Plasma Induction Apparatus

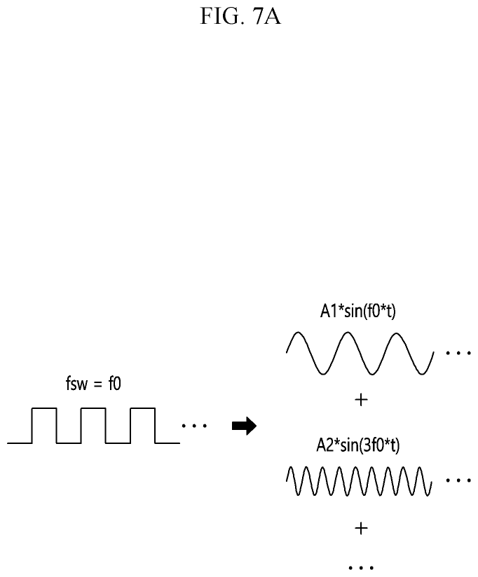

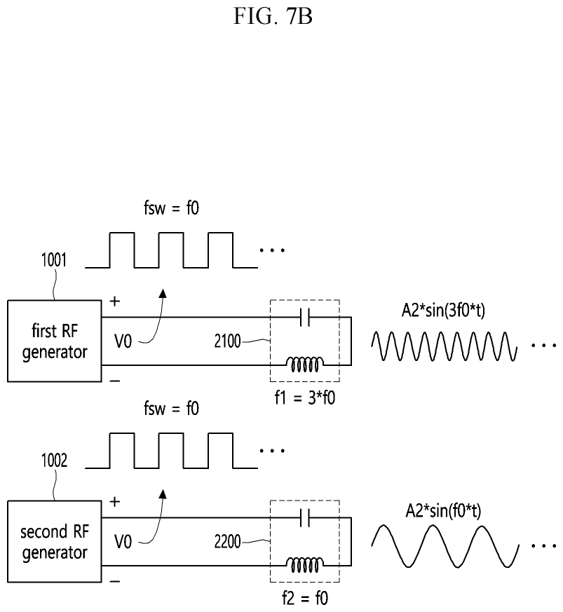

Hereinafter, a plasma induction apparatus 2000 designed to minimize the influence of inductive interaction between loads will be described with reference to FIGS. 7A and 7B.

FIGS. 7A and 7B are a diagram illustrating that the square wave component affected by each load changes depending on the resonant frequency design of the loads, according to an embodiment. FIG. 7A is a diagram illustrating that the square wave includes multiple sinusoidal wave components, and FIG. 7B is a diagram illustrating that the loads are affected by specific components included in the square wave when each load is designed to have a specific resonant frequency.

### 2.1 Analysis of Square Wave Components

A square wave may contain multiple sinusoidal components. A square wave with a fundamental frequency may be understood as a composite wave of sinusoids with frequencies of (2n−1) times (n is a natural number) of the fundamental frequency through Fourier series. For example, referring to FIG. 7A, in the case of a square wave with a fundamental frequency f0, it may be understood as a composite wave of the first sinusoid (A1 sin(f0*t)) with a frequency of f0, the second sinusoid (A2 sin(3f0*t)) with a frequency of 3f0, the third sinusoid (A3 sin(5f0*t)) with a frequency of 5f0, . . . , the nth sinusoid (An sin((2n−1)f0*t)) with a frequency of (2n−1)f0.

As described above, when the load has a specific resonant frequency and a square wave voltage is applied to the load, a large current may flow to a load due to a sine wave that has a frequency that corresponds to or is close to the resonant frequency of the load among the sine waves that make up the square wave.

Referring to FIG. 7B, when the first voltage signal applied from the first RF generator 1001 to the first load 2100 is a square wave having a fundamental frequency f0, and the ignition resonance frequency f1 of the first load 2100 is 3*f0, a high current may flow to the first load 2100 due to a sinusoidal component having a frequency of 3*f0 among components of the first voltage signal.

Meanwhile, when the second voltage signal applied to the second load 2200 from the second RF generator 1002 is a square wave having the fundamental frequency f0, and the main resonant frequency f2 of the second load 2200 is f0, a high current may flow to the second load 2200 due to a sinusoidal component having a frequency of f0 among components of the second voltage signal.

In other words, when the resonant frequency of the load is designed to be a harmonic wave frequency of the fundamental frequency of the voltage signal provided by the RF generator 1000 or to be close to it, the magnitude of the current flowing in the load may increase.

### 2.2 Design of Resonant Frequency

The ignition resonant frequency f1 of the first load 2100 and the main resonant frequency f2 of the second load 2200 may be designed differently from each other. This is to minimize the interaction occurring between the first antenna structure 2130 of the first load 2100 and the second antenna structure 2230 of the second load 2200, or the influence of the induced electromotive force.

However, in order to allow current with the strongest possible intensity to flow through both the first load 2100 and the second load 2200, it is necessary to control the frequency of the first voltage signal supplied from the first RF generator 1001 and the frequency of the second voltage signal supplied from the second RF generator 1002 to the maximum, in which the frequency of the first voltage signal and the frequency of the second voltage signal become substantially the same.

Considering this, in order to allow the maximum current to flow through the first load 2100 and the second load 2200 while minimizing the mutual inductive coupling between the first load 2100 and the second load 2200, the harmonic frequency may be used as follows.

First, the main resonant frequency f2 of the second load 2200 may be designed.

For example, the main resonant frequency f2 may be selected from a frequency range that the second voltage signal provided by the second RF generator 1002 may have.

As another example, when the second RF generator 1002 has a specific frequency as a driving frequency by default, the main resonant frequency f2 may be designed to have the corresponding driving frequency or a value close to it.

As another example, when the second voltage signal provided by the second RF generator 1002 has a driving frequency depending on the process or environment in which the plasma induction system 100 is used, the main resonant frequency f2 may be designed to have the corresponding driving frequency or a value close to it.

As another example, the main resonant frequency f2 of the second load 2200 may be designed according to a type or environment of the process in which the plasma induction system 100 is used. Specifically, the higher the pressure inside the discharge tube 2300, the more difficult it is to induce plasma. Therefore, the intensity and variation of the electromagnetic field formed by the load need to be increased, and for this purpose, the frequency of the voltage signal applied to the load needs to be greater than or equal to a certain value. In other words, the main resonant frequency f2 of the second load 2200 may be designed based on at least one of the size of the discharge tube 2300, the pressure inside the discharge tube 2300 during the plasma process, the type of gas required for discharge, the supply flow rate of the gas, the maximum power capable of being supplied by the RF generator 1000, the physical size (e.g., diameter) of the second load 2200, and the size of the second voltage signal applied to the second load 2200.

The ignition resonant frequency f1 of the first load 2100 may be determined in a similar manner to the method of determining the main resonant frequency f2 of the second load 2200 described above.

For example, the ignition resonant frequency f1 may be determined as (2n+1) times a frequency selected from the frequency range of the first voltage signal provided by the first RF generator 1001.

As another example, when the first RF generator 1001 has a specific frequency as a driving frequency by default, the ignition resonance frequency f1 may be designed to have (2n+1) times the driving frequency or a value close thereto.

As another example, when the first voltage signal provided by the first RF generator 1001 has a driving frequency depending on the process or environment in which the plasma induction system 100 is used, the ignition resonance frequency f1 may be designed to have (2n+1) times the driving frequency or a value close to it.

As another example, the ignition resonance frequency f1 of the first load 2100 may be designed depending on the type or environment of the process in which the plasma induction system 100 is used. Specifically, the ignition resonance frequency f1 of the first load 2100 may be designed based on any one of the size of the discharge tube 2300, the pressure inside the discharge tube 2300 during the plasma process, the physical size (e.g., diameter) of the first load 2100, and the size of the first voltage signal applied to the first load 2100.

Meanwhile, the ignition resonant frequency f1 of the first load 2100 may be determined based on the main resonant frequency f2 of the second load 2200. For example, the ignition resonant frequency f1 may be determined as (2n+1) times the main resonant frequency f2.

Conversely, the main resonant frequency f2 of the second load 2200 may be determined based on the ignition resonant frequency f1 of the first load 2100. For example, the main resonant frequency f2 may be determined as a value obtained by dividing the ignition resonant frequency f1 by (2n+1).

As described above, when the ignition resonant frequency f1 of the first load 2100 and the main resonant frequency f2 of the second load 2200 are designed, the frequency range where the current flowing in the first load 2100 reaches its maximum and the frequency range where the current flowing in the second load 2200 reaches its maximum are far apart from each other. Herein, the influence of the interaction between the first load 2100 and the second load 2200 is reduced as follows.

First, when a first voltage signal having a driving frequency substantially equal to the ignition resonant frequency f1 is applied to the first load 2100, a current having a frequency substantially equal to the ignition resonant frequency f1 flows to the first load 2100. Herein, the electromotive force induced in the second load 2200 has a frequency in a different band from the main resonant frequency f2, which results that the magnitude of the current flowing in the second load 2200 does not exceed a critical size that causes abnormal operation of the plasma induction system 100 or damage in some components.

Likewise, when a second voltage signal having a driving frequency substantially equal to the main resonant frequency f2 is applied to the second load 2200, a current having a frequency substantially equal to the main resonant frequency f2 flows to the second load 2200. Herein, the electromotive force induced in the first load 2100 has a frequency of band different from that of the ignition resonant frequency f1, which results that the magnitude of the current flowing in the first load 2100 does not exceed a critical size that causes abnormal operation of the plasma induction system 100 or damage in some components.

### 3. Method of Controlling Plasma Induction Apparatus

Hereinafter, with reference to FIGS. 8 to 12, a method for controlling a plasma induction system 100 will be described.

### 3.1 Method of Controlling Plasma Induction System

FIG. 8 is a flowchart illustrating a method of controlling a plasma induction system 100 according to an embodiment.

Referring to FIG. 8, the control method may include a step of supplying auxiliary gas into a discharge tube 2300 (S1100), a step of applying voltage to a first load 2100 (S1200), a step of determining whether plasma is ignited (S1300), a step of performing frequency tracking for the first load 2100 (S1400), a step of applying voltage to a second load 2200 (S1500), a step of determining whether the plasma has transitioned (S1600), a step of performing frequency tracking for the second load 2200 (S1700), a step of supplying a gas to be reformed into a discharge tube 2300 (S1800), and a step of stopping applying voltage to the first load 2100 (S1900).

Hereinafter, each step will be described in detail.

First, auxiliary gas may be supplied into the discharge tube 2300 (S1100). The auxiliary gas is a gas used to ignite plasma, such as argon gas or helium gas, and may be understood as a gas for increasing the electron density in the discharge tube 2300.

Referring to FIG. 5, the auxiliary gas may be introduced into the discharge tube 2300 through a swirl generating unit provided at the top of the discharge tube 2300.

A voltage may be applied to the first load 2100 (S1200). For example, the first RF generator 1001 may apply a first voltage signal having a first initial driving frequency to the first load 2100. Herein, the first initial driving frequency may be a value obtained by dividing the ignition resonance frequency f1 of the first load 2100 by (2n+1), or a value similar thereto (within a certain error range, for example, 0 to 10%).

Herein, when the voltage signal having the first initial driving frequency is applied to the first load 2100, the first initial driving frequency may be determined so that the magnitude of the current flowing in the first load 2100 does not exceed the maximum allowable current value of the first RF generator 1001.

When voltage is applied to the first load 2100, an electric field is formed in the discharge tube 2300 by the ignition antenna structure 2130, and the auxiliary gas introduced into the discharge tube 2300 is accelerated by the electric field and thus phase-transitions into plasma. During the plasma ignition process, the plasma changes from the E-mode in which capacitive coupling is dominant, to the H-mode in which inductive coupling is dominant, as the electron density increases.

Steps S1100 and S1200 may be performed simultaneously. Alternatively, step S1200 may be performed before step S1100.

Meanwhile, a DC pulse may be applied to a direct current (DC) electrode positioned outside the discharge tube 2300 before or after step S1200 is performed. For example, as shown in FIG. 5, a pulse voltage may be applied to a DC electrode positioned adjacent to the first region R1 for plasma ignition. However, the process of applying a pulse voltage to the DC electrode does not necessarily have to be performed.

Thereafter, it may be determined whether plasma has ignited (S1300).

Whether the plasma has ignited may be determined based on a phase difference between the voltage applied to the first load 2100 and the current flowing in the first load 2100. For example, the first control unit of the first RF generator 1001 may determine that the plasma has ignited when the first phase difference condition is satisfied that the phase of the current flowing in the first load 2100 is ahead of the phase of the voltage applied to the first load 2100. As another example, the first control unit of the first RF generator 1001 may measure the phase difference between the current flowing in the first load 2100 and the voltage applied based on the time point at which the voltage signal is applied to the first load 2100, and then determine that the plasma has ignited when the second phase difference condition is satisfied that the phase of the current flowing in the first load 2100 is ahead of the phase of the voltage applied to the first load 2100.

Alternatively, whether the plasma has ignited may be determined based on the power consumed by the first load 2100. For example, the first control unit of the first RF generator 1001 may determine that the plasma is ignited when the first power condition is satisfied in which the amount of power consumed by the first load 2100 is greater than or equal to a first predetermined threshold power value. In the case of the control method of the plasma induction system 100 described in the present disclosure, it may be more appropriate to use the power condition rather than the phase difference condition in determining whether the plasma has ignited. It is because that the phase of the current flowing in the first load 2100 and the phase of the voltage applied to the first load 2100 may change irregularly in order, since the driving frequency of the voltage applied to the first load 2100 corresponds to the first resonant frequency of the first load 2100.

Alternatively, the first control unit of the first RF generator 1001 may determine that the plasma has ignited when at least one of the first phase difference condition, the second phase difference condition, and the first power condition is satisfied.

The first phase sensing module and/or the first power sensing module of the first RF generator 1001 may be used when the first control unit of the first RF generator 1001 determines whether the plasma has ignited.

Meanwhile, whether the plasma has ignited may be determined by the system control unit. For example, the system control unit may obtain data from the first phase sensing module and/or the first power sensing module to determine whether the plasma has ignited, and when it is determined that the plasma has ignited, may control the first RF generator 1001 to perform frequency tracking on the first load 2100 or control the second RF generator 1002 to apply a voltage signal to the second load 2200.

The frequency tracking may be performed on the first load 2100 (S1400). As the plasma is ignited, a load including an inductive component called plasma (hereinafter, plasma load) in addition to the first load 2100 is added to the output terminal of the first RF generator 1001. Accordingly, the first RF generator 1001 applies voltage to a first synthetic load that is a synthesis of the first load 2100 and the plasma load, and the inductance of the plasma load is not constant but variable, so that resonant frequency of the first synthetic load also becomes variable. As the resonant frequency of the first synthetic load connected to the output terminals of the first RF generator 1001 becomes variable, it is necessary to change the driving frequency of the voltage signal applied to the first synthetic load from the first RF generator 1001 in real time to approach a variable resonant frequency, in order to continuously supply maximum energy to the first synthetic load or the plasma load.

In other words, the first RF generator 1001 may increase or decrease the driving frequency of the voltage signal supplied to reduce the phase difference between the current flowing in the first load 2100 and the voltage applied, which is called frequency tracking. In general, in the frequency tracking process, the driving frequency of the voltage signal applied to the first load 2100 may have a value greater than the first initial driving frequency described above. A specific method of performing frequency tracking on the first load 2100 will be described later.

Meanwhile, the resonant frequency of the first synthetic load may be obtained as the driving frequency of the voltage signal output from the first RF generator 1001 when the difference between the phase of the current flowing in the first load 2100 and the phase of the voltage applied to the first load 2100 is 0 or substantially equal to 0.

A voltage may be applied to the second load 2200 for plasma transitions and maintenance (S1500). For example, the second RF generator 1002 may apply a second voltage signal having a second initial driving frequency to the second load 2200. Herein, the second initial driving frequency may be the main resonant frequency f2 of the second load 2200 or a value similar thereto (within a certain error range, for example, 0 to 10%). In addition, the second initial driving frequency may be substantially the same as or similar to the first initial driving frequency.

Step S1500 is not necessarily performed after step S1400. For example, the second voltage signal may also be applied to the second load 2200 at the time when the first voltage signal is applied to the first load 2100. As another example, the second voltage signal may be applied to the second load 2200 before the first voltage signal is applied to the first load 2100, and the first voltage signal may not be applied to the first load 2100 depending on whether the plasma has ignited. As another example, the second voltage signal may be applied to the second load 2200 when it is determined that the plasma has ignited. As another example, the second voltage signal may be applied to the second load 2200 at the time when frequency tracking is performed for the first load 2100.

It is determined whether plasma has transitioned (S1600). The plasma transition means that plasma ignited in the first region R1 of the discharge tube 2300 by the first load 2100 moves to the second region R2 surrounded by the second load 2200. When voltage is applied to the second load 2200, an electromagnetic field is formed in the second region R2 by the main antenna structure 2230, and plasma particles in the H mode move to the second region R2 to maintain the plasma state.

The determination of whether the plasma has transitioned may be made in the same manner as the determination of plasma ignition.

Whether the plasma has transitioned may be determined based on the phase difference between the voltage applied to the second load 2200 and the current flowing in the second load 2200. For example, the second control unit of the second RF generator 1002 may determine that plasma has transitioned when the third phase difference condition is satisfied that the phase of the current flowing in the second load 2200 is ahead of the phase of the voltage applied to the second load 2200. As another example, the second control unit of the second RF generator 1002 measures the phase difference between the current flowing in the second load 2200 and the applied voltage based on the time point at which the voltage signal is applied to the second load 2200 and then, when the fourth phase difference condition is satisfied that the phase of the current flowing in the second load 2200 is ahead of the phase of the voltage applied to the second load 2200, determine that the plasma has transitioned.

Alternatively, whether the plasma has transitioned may be determined based on the power consumed by the second load 2200. For example, the second control unit of the second RF generator 1002 may determine that the plasma has transitioned when a second power condition is satisfied that the amount of power consumed by the second load 2200 is greater than or equal to a second predetermined threshold power value. In the case of the control method of the plasma induction system 100 described in the present disclosure, it may be more appropriate to use a power condition rather than a phase difference condition in determining whether the plasma has transitioned. It is because that the phase of the current flowing in the second load 2200 and the phase of the voltage applied to the second load 2200 may change irregularly in order, Since the driving frequency of the voltage applied to the second load 2200 corresponds to the main resonant frequency f2 of the second load 2200,

Alternatively, the second control unit of the second RF generator 1002 may determine that the plasma has transitioned when at least one of the third phase difference condition, the fourth phase difference condition, and the second power condition described above is satisfied.

The second phase sensing module and/or the second power sensing module of the second RF generator 1002 may be used when the second control unit of the second RF generator 1002 determines whether the plasma has transitioned.

Meanwhile, as described below, when steps S1500 and S1700 are performed together, that is, when frequency tracking is performed for the second load 2200 before plasma transitions, whether the plasma transitions may be determined based on the degree to which the driving frequency of the voltage signal output from the second RF generator 1002 changes. For example, when the second RF generator 1002 performs frequency tracking for the second load 2200, as described below, when plasma transitions, a phase difference occurs between the current and the voltage applied to the second load 2200, and accordingly, the driving frequency of the voltage signal output from the second RF generator 1002 changes. Therefore, when the amount of change in the driving frequency of the voltage signal output from the second RF generator 1002 is greater than or equal to a predetermined value, it may be determined that the plasma is transitioned.

Whether plasma has transitioned may be determined by the system control unit. For example, the system control unit may obtain data from the second phase sensing module and/or the second power sensing module to determine whether plasma has transitioned, and when it is determined that plasma has transitioned, control the second RF generator 1002 to perform frequency tracking for the second load 2200 or control the first RF generator 1001 to stop applying a voltage signal to the first load 2100.

Frequency tracking may be performed for the second load 2200 (S1700). As the plasma transitions, the second load 2200, as well as the plasma load including an inductive component are added to the output terminals of the second RF generator 1002. Accordingly, the second RF generator 1002 applies voltage to the second synthetic load which is a synthesis of the second load 2200 and the plasma load, and the resonance frequency of the second synthetic load becomes variable, like the first synthetic load. In order to continuously supply maximum energy to the second synthetic load or the plasma load, it is necessary to change the driving frequency of the voltage signal applied to the second synthetic load from the second RF generator 1002 in real time so that it approaches the variable resonance frequency.

In other words, the second RF generator 1002 may increase or decrease the driving frequency of the voltage signal supplied to reduce the phase difference between the current flowing in the second load 2200 and the voltage applied. In general, the driving frequency of the voltage signal applied to the second load 2200 in the frequency tracking process may have a value greater than the second initial driving frequency described above. A specific method of performing frequency tracking for the second load 2200 will be described later.

Meanwhile, the resonant frequency of the second synthetic load may be obtained as the driving frequency of the voltage signal output from the second RF generator 1002 when the difference between the phase of the current flowing in the second load 2200 and the phase of the voltage applied to the second load 2200 is 0 or substantially equal to 0.

The plasma ignited in the first region R1 in steps S1500 to S1700 may move to the second region R2 and reach a steady state in which it is stably maintained.

Meanwhile, step S1700 may also be performed together with step S1500. In other words, the second RF generator 1002 may perform frequency tracking for the second load 2200 while applying voltage to the second load 2200.

A gas to be reformed may be supplied into the discharge tube 2300 (S1800). Specifically, a first feed gas, a second feed gas, and water vapor may be supplied into the discharge tube 2300. They may be reformed into a synthesis gas by the plasma induced in the discharge tube 2300.

Step S1800 does not necessarily have to be performed after step S1700, and may be performed between steps S1100 and S1700. For example, the gas to be reformed may be supplied together with the auxiliary gas when it is supplied into the discharge tube 2300. As another example, the gas to be reformed may be supplied into the discharge tube 2300 at a time when it is determined that the plasma has been ignited. As still another example, the gas to be reformed may be supplied into the discharge tube 2300 when the voltage signal is applied to the second load 2200.

The application of the voltage signal to the first load 2100 may be stopped (S1900). In the case that the plasma is stably maintained in the second region R2, since there is a risk that the plasma may move to the first region R1 when the voltage signal is applied to the first load 2100, the application of the voltage signal to the first load 2100 must be stopped, in which the timing may be within the section where steps S1500 to S1800 are performed.

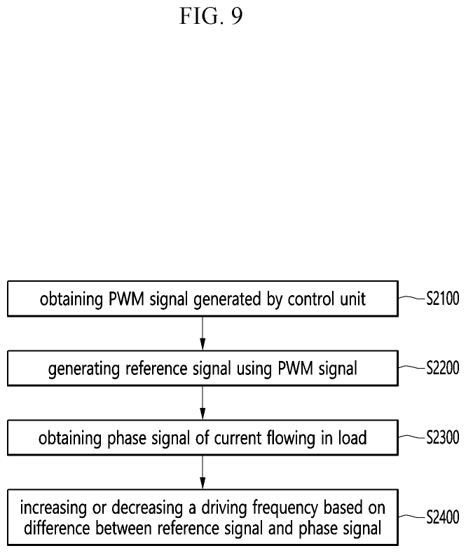

Hereinafter, a frequency tracking method will be described with reference to FIGS. 9 to 12.

### 3.2 Frequency Tracking Method

FIG. 9 is a flowchart illustrating a frequency tracking method (or a basic frequency tracking method) for a load according to an embodiment. Referring to FIG. 9, the frequency tracking method may include a step of obtaining a pulse width modulation (PWM) signal provided by a control unit 1600 (S2100), a step of generating a reference signal using the PWM signal (S2200), a step of obtaining a phase signal of a current flowing in a load (S2300), and a step of increasing or decreasing a driving frequency based on a difference between the reference signal and the phase signal (S2400).

Hereinafter, each step is described in detail. Below, considering it is assumed that the frequency tracking method is performed in the control unit 1600 for convenience of explanation, a method will be described in which the control unit 1600 applies a voltage signal having the driving frequency before change to the load in the first time duration, and calculates the driving frequency after change when applying a voltage signal having the driving frequency after change to the load in the second time duration after the first time duration.

The control unit 1600 may obtain the first pulse width modulation (PWM) signal output in the first time duration (S2100). Here, the first PWM signal may correspond to a switch signal provided to one of the switches of the inverter 1300 by the control unit 1600 in the first time duration. The switch signal may be, for example, a signal received by the first switch among the switches of the inverter 1300. The frequency of the switch signal is the same as the driving frequency of the voltage signal applied to the load in the first time duration.

The control unit 1600 may generate the reference signal using the first PWM signal (S2200). The first PWM signal passes through a transmission circuit such as a gate driver or a signal isolator until it reaches the switch of the inverter 1300, which causes a time delay between the first PWM signal and the switch signal received by the switch. Therefore, in order to more clearly estimate the phase of the voltage applied to the load, the control unit 1600 may generate the reference signal by delaying the first PWM signal for a certain period of time. The reference signal may be understood as a virtually generated signal for calculating a phase difference, not a signal actually output from the control unit 1600.

The reference signal may be determined differently depending on whether it is operated in complete resonance, whether it is operated inductively, and whether it is operated capacitively, for the composite load of the load and the plasma load. For example, in the case that the time delay between the first PWM signal and the switch signal is a fixed delay time, when it is operated in complete resonance, the first PWM signal is delayed by the fixed delay time to generate the reference signal, and when it is operated inductively, the first PWM signal is delayed by a first delay time longer than the fixed delay time to generate the reference signal, and when it is operated capacitively, the first PWM signal is delayed by a second delay time shorter than the fixed delay time to generate the reference signal.

The control unit 1600 may obtain the phase signal of the current flowing in the load (S2300). For example, the control unit 1600 may obtain the phase signal of the current flowing in the load from the phase sensing module 1400.

The control unit 1600 may increase or decrease the driving frequency based on the reference signal and the phase signal (S2400). For example, the control unit 1600 may decrease the driving frequency by a predetermined adjustment value when the reference signal is faster than the phase signal. In other words, the control unit 1600 may output the second PWM signal having a frequency less than the first PWM signal in the second time duration. As another example, the control unit 1600 may increase the driving frequency by the adjustment value when the reference signal is slower than the phase signal. In other words, the control unit 1600 may output the second PWM signal having a greater frequency than the first PWM signal in the second time duration. For another example, the control unit 1600 may output the second PWM signal having the same frequency as the first PWM signal in the second time duration when the size of the delay time between the reference signal and the phase signal is less than or equal to a threshold value.

### 3.3 Frequency Tracking During Harmonic Driving

The plasma induction system 100 may perform the above-described frequency tracking method when inducing plasma. Specifically, the RF generator 1000 may periodically change or maintain the driving frequency through the frequency tracking method when applying a voltage having the driving frequency to the plasma induction apparatus 2000. For example, in steps S1400 and S1700 described in FIG. 8, each of the first RF generator 1001 and the second RF generator 1002 may perform the above-described frequency tracking, and accordingly plasma ignition and maintenance may be smoothly performed.

In the case of the first RF generator 1001, a problem may occur when the above-described frequency tracking method is performed as it is, because the ignition resonance frequency f1 of the first load 2100 is harmonic frequency and thus relatively larger than the driving frequency set in the first RF generator 1001 due to the harmonic. More specifically, the above-described frequency tracking method requires a voltage phase signal and a current phase signal. Here, since the voltage phase signal is replaced with the PWM signal of the first control unit of the first RF generator 1001, the frequency of the voltage phase signal is substantially the same as the driving frequency of the first RF generator 1001. Meanwhile, since the current phase signal directly measures the current flowing in the first load 2100, the frequency of the current phase signal is a harmonic frequency, which is the resonance frequency of the first load 2100, or is close to it. In other words, the frequency levels of the voltage phase signal and the current phase signal compared by the first RF generator 1001 for frequency tracking are different from each other, making it difficult to accurately measure the phase difference.

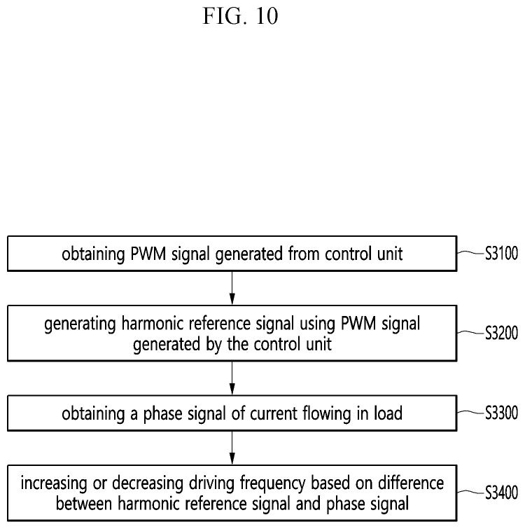

Hereinafter, referring to FIGS. 10 to 12, the frequency tracking method is described in which a voltage signal having an initial driving frequency (or fundamental driving frequency) is output from an RF generator 1000 and the resonant frequency of the load is designed as a harmonic of the initial driving frequency.

FIG. 10 is a flowchart illustrating a harmonic frequency tracking method for a load having a harmonic frequency as a resonant frequency according to an embodiment. Referring to FIG. 10, the harmonic frequency tracking method may include a step of obtaining a PWM signal generated from a control unit 1600 (S3100), a step of generating a harmonic reference signal using the PWM signal (S3200), a step of obtaining a phase signal of a current flowing in a load (S3300), and a step of increasing or decreasing a driving frequency based on a difference between the harmonic reference signal and the phase signal (S3400).

Hereinafter, each step is described in detail. As with the above-described frequency tracking method, it is assumed that the control unit 1600 determines the driving frequency in the second time duration based on information in the first time duration.

First, since step S3100 is the same as step S2100, the overlapping content is omitted. In step S3100, the control unit 1600 may obtain the first PWM signal output in the first time duration.

The control unit 1600 may generate a harmonic reference signal using the first PWM signal (S3200). For example, the harmonic reference signal may be generated by delaying a signal having a harmonic frequency of the first PWM signal by a fixed delay time. For another example, the harmonic reference signal may be generated by delaying the first PWM signal by the fixed delay time and then changing the frequency to a harmonic frequency.

Here, the order of the harmonic to be changed may be determined based on at least one of the initial driving frequency configured in the RF generator 1000 and the resonant frequency of the load. For example, when the driving frequency of the voltage initially output for plasma induction from the first RF generator 1001 is the first initial driving frequency, and the ignition resonant frequency f1 of the first load 2100 is (2n+1) times the first initial driving frequency, the order of the harmonic becomes (2n+1) when generating the harmonic reference signal.

As with the aforementioned frequency tracking method, the harmonic reference signal may be generated with different delay levels depending on how the load is operated.

The control unit 1600 may obtain a phase signal of the current flowing in the load (S3300). For example, the control unit 1600 may obtain the phase signal of the current flowing in the load from the phase sensing module 1400.

The control unit 1600 may increase or decrease the driving frequency based on the harmonic reference signal and the phase signal (S3400). For example, the control unit 1600 may decrease the driving frequency when the harmonic reference signal is faster than the phase signal. In other words, the control unit 1600 may output a second PWM signal having a frequency less than the first PWM signal in the second time duration. As another example, the control unit 1600 may increase the driving frequency when the harmonic reference signal is slower than the phase signal. In other words, the control unit 1600 may output the second PWM signal having a greater frequency than the first PWM signal in the second time duration. As another example, the control unit 1600 may output the second PWM signal having the same frequency as the first PWM signal in the second time duration when the size of the delay time between the harmonic reference signal and the phase signal is less than or equal to a threshold value.

Meanwhile, the degree of increasing or decreasing the driving frequency in the harmonic frequency tracking method may be different from the degree of increasing or decreasing the driving frequency in the frequency tracking method. For example, the first RF generator 1001 may output a voltage signal having a first driving frequency in the first time duration, and may output a voltage signal having a second driving frequency in the second time duration by performing the harmonic frequency tracking method. In addition, the second RF generator 1002 may output a voltage signal having a third driving frequency in the third time duration, and may output a voltage signal having a fourth driving frequency in the fourth time duration by performing the frequency tracking method. Herein, a difference between the first driving frequency and the second driving frequency (e.g., the first adjustment value) may be smaller than a difference between the third driving frequency and the fourth driving frequency (e.g., the second adjustment value). This is because the first load 2100 to which the first RF generator 1001 provides a voltage signal is affected by harmonic components, and thus is more affected by the difference in driving frequency, rather than the second load 2200.

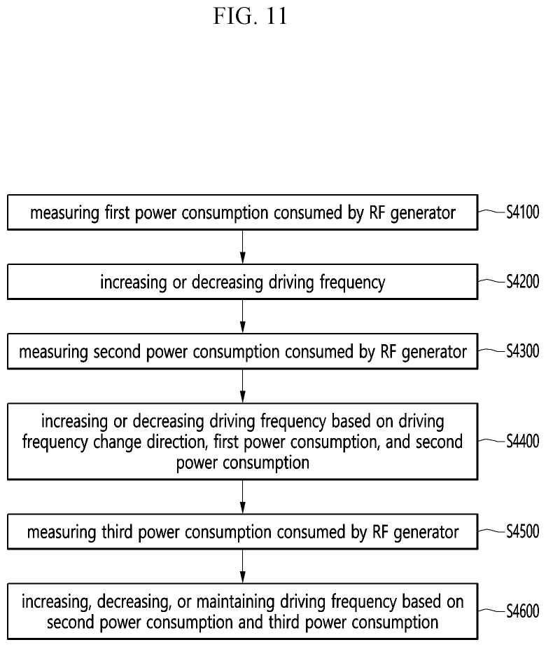

Hereinafter, a frequency tracking method based on power consumption is described with reference to FIG. 11.

FIG. 11 is a flowchart illustrating a frequency tracking method based on power consumption for a load having a harmonic frequency as a resonant frequency according to an embodiment.

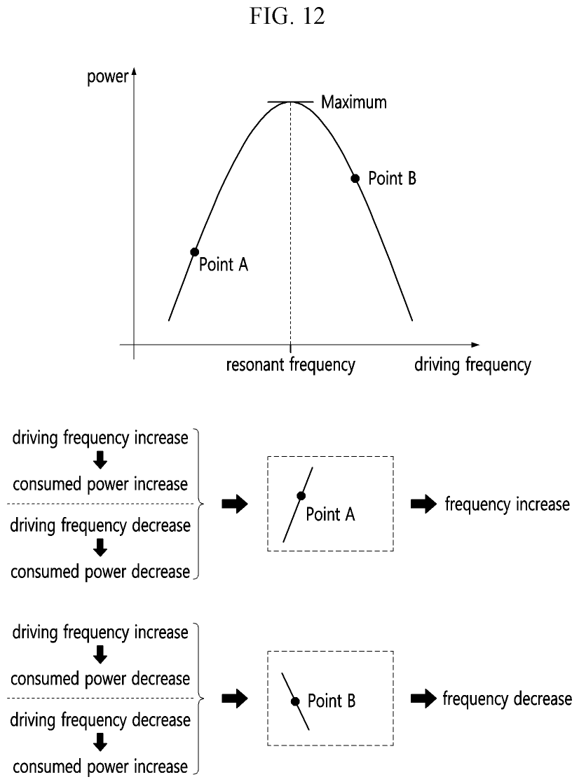

FIG. 12 is a diagram illustrating a frequency tracking method based on power consumption according to an embodiment.

The closer the driving frequency of the voltage signal applied to the load is to the resonant frequency of the load, the greater the power is consumed by the load. Meanwhile, the further the driving frequency of the voltage signal applied to the load is from the resonant frequency of the load, the smaller the power is consumed by the load. Considering this, the power consumed by the load may be measured while changing the driving frequency of the voltage signal applied to the load, and the driving frequency may be changed to be closer to the resonant frequency of the load according to the change in power.

Referring to FIG. 11, the frequency tracking method based on power consumption may include a step of measuring a first power consumption consumed by an RF generator 1000 (S4100), a step of increasing or decreasing a driving frequency (S4200), a step of measuring a second power consumption consumed by an RF generator 1000 (S4300), a step of increasing or decreasing a driving frequency based on a driving frequency change direction, the first power consumption, and the second power consumption (S4400), a step of measuring a third power consumption consumed by the RF generator 1000 (S4500), and a step of increasing, decreasing, or maintaining a driving frequency based on the second power consumption and the third power consumption (S4500).

Hereinafter, for convenience of explanation, it is assumed that the RF generator 1000 outputs a first voltage signal having a first driving frequency in a first time duration, outputs a second voltage signal having a second driving frequency in a second time duration, outputs a third voltage signal having a third driving frequency in a third time duration, and outputs a fourth voltage signal having a fourth driving frequency in a fourth time duration. Herein, steps S4100 to S4600 are performed in a time series manner, in which step S4100 is performed in a first time duration, the first time duration and the second time duration being distinguished based on step S4200, step S4300 is performed in a second time duration, the second time duration and the third time duration being distinguished based on step S4400, and step S4500 is performed in a third time duration, the third time duration and the fourth time duration being distinguished based on step S4600.

Each step is described in detail hereinafter.

First, the first power consumption consumed by the RF generator 1000 may be measured (S4100).

For example, the RF generator 1000 may obtain the first power consumption by measuring the power consumption based on the input terminals of the inverter 1300. Specifically, the control unit 1600 may measure the power consumed by the inverter 1300 and the load using the power sensing module 1500. The first power consumption may be a power value measured at a point in time, or a value calculated by averaging the power measured over a certain time period. For example, the control unit 1600 may obtain the first power consumption by measuring the power consumption over a time period of a predetermined length and calculating the average.

As another example, the RF generator 1000 may obtain the first power consumption by measuring the power consumption based on the output terminal of the inverter 1300. Specifically, the control unit 1600 may obtain the first power consumption by measuring the voltage applied and current flowing to the output terminals of the inverter 1300, i.e., the load. Similarly, the first power consumption may be a value measured at a point in time, or a value obtained by averaging the power measured over a certain period of time.

Afterwards, the RF generator 1000 may increase or decrease a driving frequency of an output voltage signal (S4200). For example, the RF generator 1000 may output a voltage signal having a first driving frequency in a first time duration and a voltage signal having a second driving frequency different from the first driving frequency in a second time duration. Herein, the second driving frequency may be less or greater than the first driving frequency. For example, the second driving frequency has a value increased or decreased by a predetermined increase/decrease ratio based on the first driving frequency, and the increase/decrease ratio may be determined between about 1% and about 10%.

It may be noted that step S4200 is a process of arbitrarily changing the driving frequency to determine the relationship between the current driving frequency and the resonant frequency of the synthesized load, as described below.

The second power consumption consumed by the RF generator 1000 may be measured (S4300). For example, the RF generator 1000 may measure the second power consumption in the second time period in which it outputs the voltage signal having the changed second driving frequency. The method for measuring the second power consumption is the same as the method for measuring the first power consumption in step S4100, so the description is omitted.

The RF generator 1000 may increase or decrease the driving frequency based on a change in the driving frequency, the first power consumption, and the second power consumption (S4400). For example, the RF generator 1000 may increase or decrease the driving frequency depending on a driving frequency increase or decrease rule. The driving frequency increase or decrease rule is described in detail with reference to FIG. 12.

First, referring to FIG. 12, the relationship between driving frequency and power may be represented as a convex graph shape, in which the power consumption is maximum when the driving frequency becomes the resonant frequency of the synthetic load.

In other words, when the current position is identified on the graph of the relationship between the driving frequency and the power consumption, the driving frequency may be increased or decreased based on this. For example, when the position of the driving frequency based on the resonant frequency of the synthetic load (hereinafter referred to as the ‘driving frequency position’) in the graph illustrated in FIG. 12 is determined to correspond to a point A, the RF generator 1000 may increase the driving frequency. As another example, when the position of the driving frequency is determined to correspond to a point B in the graph illustrated in FIG. 12, the RF generator 1000 may decrease the driving frequency. For convenience of explanation, a state in which the driving frequency is less than the resonant frequency of the synthetic load is referred to as the first state, and a state in which the driving frequency is larger than the resonant frequency of the synthetic load is referred to as the second state.

The cases of power consumption increasing or decreasing due to driving frequency increase or decrease may be divided into the following four cases:

1) Case of Power Consumption Increasing when Driving Frequency Increases

When the second driving frequency of the second time duration is greater than the first driving frequency of the first time duration, and the second power consumption measured in the second time duration has a larger value than the first power consumption measured in the first time duration, a state of the RF generator 1000 is the first state in which the driving frequency is less than the resonant frequency of the synthetic load.

Therefore, in step S4400, the RF generator 1000 may increase the driving frequency of the voltage signal applied to the load. In other words, the third driving frequency of the third time duration may be made greater than the second driving frequency of the second time duration by a predetermined third adjustment value.

2) Case of Power Consumption Reduction when Driving Frequency is Reduced

When the second driving frequency of the second time duration is less than the first driving frequency of the first time duration, and the second power consumption measured in the second time duration has a smaller value than the first power consumption measured in the first time duration, a state of the RF generator 1000 is the first state in which the driving frequency is less than the resonant frequency of the synthetic load.

Therefore, in step S4400, the RF generator 1000 may increase the driving frequency of the voltage signal applied to the load. In other words, the third driving frequency of the third time duration may be made greater than the second driving frequency of the second time duration by a predetermined third adjustment value.

3) Case of Power Consumption Reduction when Driving Frequency Increases

When the second driving frequency of the second time duration is greater than the first driving frequency of the first time duration, and the second power consumption measured in the second time duration is smaller than the first power consumption measured in the first time duration, a state of the RF generator 1000 is the second state in which the driving frequency is greater than the resonant frequency of the synthetic load.

Therefore, in step S4400, the RF generator 1000 may decrease the driving frequency of the voltage signal applied to the load. In other words, the third driving frequency of the third time duration may be made less than the second driving frequency of the second time duration by a predetermined third adjustment value.

4) Case of Increased Power Consumption when the Driving Frequency is Decreased

When the second driving frequency of the second time duration is less than the first driving frequency of the first time duration, and the second power consumption measured in the second time duration has a larger value than the first power consumption measured in the first time duration, a state of the RF generator 1000 is the second state in which the driving frequency is larger than the resonant frequency of the synthetic load.

Therefore, in step S4400, the RF generator 1000 may decrease the driving frequency of the voltage signal applied to the load. In other words, the third driving frequency of the third time duration may be made less than the second driving frequency of the second time duration by a predetermined third adjustment value.

After the driving frequency is increased or decreased, the third power consumption consumed by the RF generator 1000 may be measured (S4500). For example, when a third voltage signal having a third driving frequency increased or decreased based on the second driving frequency is output in a third time duration, the RF generator 1000 may measure the third power consumption in the third time duration. Since the method of measuring the third power consumption is the same as the method of measuring the first power consumption in step S4100, the description is omitted.

The RF generator 1000 may increase, decrease, or maintain the driving frequency based on the second power consumption and the third power consumption (S4600). In step S4600, the RF generator 1000 may increase or decrease the driving frequency, but may also maintain the driving frequency when a specific condition is satisfied. Specifically, the RF generator 1000 may determine the fourth driving frequency in the fourth time duration depending on the state of the RF generator 1000 confirmed in step S4400 (the relationship between the driving frequency and the resonant frequency of the synthetic load) and whether the third power consumption power increases or decreases compared to the second power consumption. The method of determining the fourth driving frequency may be divided into several cases as described below.

1) Case in which the power consumption increases when the driving frequency increases, in a state that the driving frequency is less than the resonant frequency of the synthetic load

When the RF generator 1000 determines that the state of the RF generator 1000 is the first state while performing step S4400, and outputs a third voltage signal having a third driving frequency greater than the second driving frequency in the third time duration, the third power consumption may increase. In this case, it means that the third driving frequency is still less than the resonance frequency of the synthetic load. In other words, the state of the RF generator 1000 in the third time duration is the first state.

Therefore, the RF generator 1000 may configure the fourth driving frequency of the fourth voltage signal output in the fourth time duration to be greater than the third driving frequency by the predetermined fourth adjustment value.

2) Case in which power consumption decrease when the driving frequency increases, in a state that the driving frequency is less than the resonant frequency of the synthetic load

When the RF generator 1000 determines that the state of the RF generator 1000 is the first state while performing step S4400, and outputs a third voltage signal having a third driving frequency greater than the second driving frequency in the third time duration, the third power consumption may be reduced. Herein, it means that the third driving frequency is greater than the resonance frequency of the synthetic load. In other words, it may be understood that the state of the RF generator 1000 has changed from the first state to the second state in the third time duration.

Therefore, the RF generator 1000 may configure the fourth driving frequency of the fourth voltage signal output in the fourth time duration to be the same value as the third driving frequency. Alternatively, the RF generator 1000 may configure the fourth driving frequency to be the same value as the second driving frequency. Alternatively, the RF generator 1000 may configure the fourth driving frequency to be a value determined between the second driving frequency and the third driving frequency.

3) Case in which the power consumption increases when the driving frequency decreases, in a state that the driving frequency is greater than the resonant frequency of the synthetic load

When the RF generator 1000 determines that the state of the RF generator 1000 is the second state while performing step S4400, and outputs a third voltage signal having a third driving frequency that is less than the second driving frequency in the third time duration, the third power consumption may increase. Herein, it means that the third driving frequency is still greater than or equal to the resonance frequency of the synthetic load. In other words, the state of the RF generator 1000 in the third time duration is the second state.

Therefore, the RF generator 1000 may configure the fourth driving frequency of the fourth voltage signal output in the fourth time duration to be less than the third driving frequency by a predetermined fourth adjustment value.

4) Case in which the power consumption is reduced when the driving frequency is reduced, in a state that the driving frequency is greater than the resonant frequency of the synthetic load

When the RF generator 1000 determines that the state of the RF generator 1000 is the second state while performing step S4400, and outputs a third voltage signal having a third driving frequency that is less than the second driving frequency in the third time duration, the third power consumption may be decreased. Herein, it means that the third driving frequency is less than the resonance frequency of the synthetic load. In other words, it may be understood that the state of the RF generator 1000 has changed from the second state to the first state in the third time duration.

Therefore, the RF generator 1000 may configure the fourth driving frequency of the fourth voltage signal output in the fourth time duration to be the same value as the third driving frequency. Alternatively, the RF generator 1000 may configure the fourth driving frequency to be the same value as the second driving frequency. Alternatively, the RF generator 1000 may configure the fourth driving frequency to be a value determined between the second driving frequency and the third driving frequency.

In the frequency tracking method based on power consumption, the degree of changing the driving frequency may be closer to the degree of increasing or decreasing the driving frequency in the harmonic frequency tracking method than to the degree of increasing or decreasing the driving frequency in the frequency tracking method. For example, the third adjustment value and the fourth adjustment value may be closer to the second adjustment value rather than to the first adjustment value. As another example, the third adjustment value may be the same as the second adjustment value.

Meanwhile, the third adjustment value and the fourth adjustment value may be different from each other, and the fourth adjustment value may be smaller than the third adjustment value. This is to control the frequency finely by gradually reducing the driving frequency change amount.

The RF generator 1000 may continuously repeat the aforementioned frequency tracking method based on power consumption, so that the driving frequency maintains close to the resonant frequency of the synthetic load. For example, the RF generator 1000 may measure the power consumption again after performing step S4600 to check the direction of power consumption change, and may increase, decrease, or maintain the driving frequency based on the state of the RF generator 1000 before performing step S4600 and the direction of driving frequency change and power consumption change in step S4600.

### 3.4 ICM Control

In the plasma induction system 100, the power consumed in the plasma induction apparatus 2000 may be controlled.

The RF generator 1000 may operate in a powering mode and a freewheeling mode. In the powering mode, the RF generator 1000 may continuously apply voltage to the plasma induction apparatus 2000. In the freewheeling mode, the RF generator 1000 may alternately perform an operation of applying voltage and an operation of not applying voltage. Furthermore, in the freewheeling mode, the RF generator 1000 may control the amount of power consumed in the plasma induction apparatus 2000 by controlling the ratio of the operation of applying voltage to the operation of not applying voltage over a unit time.

### 4. Utilization of a Single RF Generator

In the foregoing, the case of using multiple RF generators 1000 in the plasma induction system 100 is mainly described. That is, the first RF generator 1001 is connected to the first load 2100, and the second RF generator 1002 is connected to the second load 2200, so that RF voltage is supplied to each.

Meanwhile, it is also possible to consider the case where multiple loads are connected to one RF generator 1000, instead of the case where the RF generator 1000 is connected to each of the multiple loads, to be supplied with RF voltage. In the case that the RF voltage is supplied to multiple loads, with a single RF generator 1000, it has a disadvantage that the control method becomes somewhat complicated and the plasma induction performance is weakened, but has a strong advantage in commercialization when considering the price and volume of the RF generator 1000.

Accordingly, the applicant additionally developed a system structure and control algorithm for applying voltage to multiple loads using one RF generator 1000.

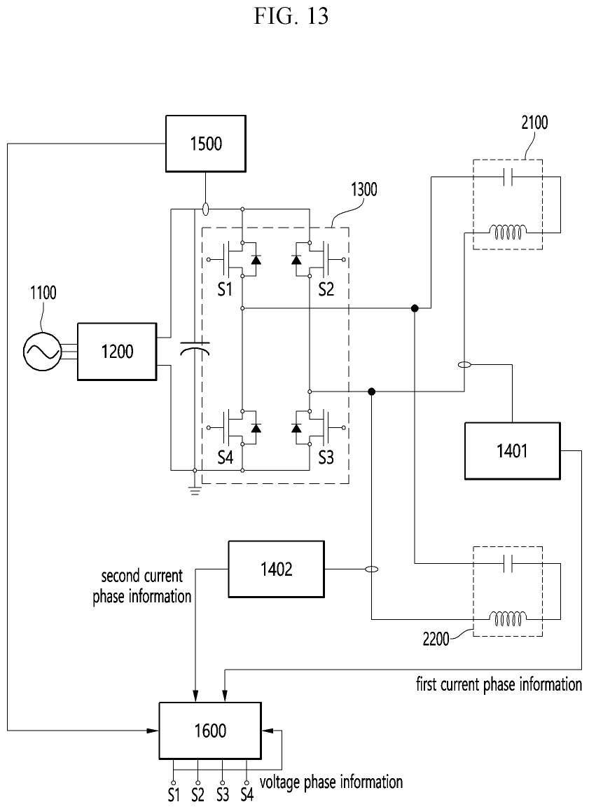

Hereinafter, a plasma induction system 100 using multiple loads and one RF generator 1000 is described with reference to FIGS. 13 to 16.

### 4.1 Circuit Structure

First, the structure of the plasma induction system 100 is described with reference to FIG. 13.

FIG. 13 is a diagram illustrating a plasma induction system 100 using multiple loads and one RF generator 1000 according to an embodiment.

Referring to FIG. 13, the first load 2100 and the second load 2200 may be connected in parallel to output terminals of an inverter 1300 of the RF generator 1000.

Additionally, the RF generator 1000 may include one inverter 1300, and may also include a first phase sensing module 1401 for detecting a current phase of the first load 2100 and a second phase sensing module 1402 for detecting a current phase of the second load 2200.

The first phase sensing module 1401 may be disposed on a circuit that electrically connects the output terminals of the inverter 1300 and the first load 2100. The second phase sensing module 1402 may be disposed on a circuit that electrically connects the output terminals of the inverter 1300 and the second load 2200.

The first phase sensing module 1401 may obtain a phase signal of the current flowing in the first load 2100 and provide it to the control unit 1600. The second phase sensing module 1402 may obtain a phase signal of the current flowing in the second load 2200 and provide it to the control unit 1600.

In FIG. 13, although the power sensing module 1500 is illustrated as one, the RF generator 1000 may include a first power sensing module corresponding to the first load 2100 and a second power sensing module corresponding to the second load 2200 as needed.

Herein, the first power sensing module may be disposed on a circuit that electrically connects the output terminals of the inverter 1300 and the first load 2100, and the second power sensing module may be disposed on a circuit that electrically connects the output terminals of the inverter 1300 and the second load 2200.

In addition, the first power sensing module may measure the current and/or voltage applied to the first load 2100 to provide data thereon to the control unit 1600. The second power sensing module may measure the current and/or voltage applied to the second load 2200 to provide data thereon to the control unit 1600.

The ignition resonant frequency f1 of the first load 2100 and the main resonant frequency f2 of the second load 2200 may be designed to be different from each other. This is to minimize the influence of the interaction between the loads as described above.

However, when designing the ignition resonant frequency f1 of the first load 2100 and the main resonant frequency f2 of the second load 2200, it is necessary to further consider the use of one RF generator 1000, which will be described in detail below.

### 4.2 Problem to be Solved

When using one RF generator 1000, voltage signals having the same driving frequency are applied simultaneously to the first load 2100 and the second load 2200.

As described above, the first load 2100 is mainly used for plasma ignition, and the second load 2200 is mainly used for plasma maintenance. Herein, the electric energy (e.g., energy by the electromagnetic field) transitioned to the plasma by the first load 2100 needs to be large to ignite the plasma, and the electric energy transitioned to the plasma by the second load 2200 needs to be large to maintain the plasma. Furthermore, in the plasma transition process, the electric energy supplied to the plasma by the first load 2100 or the electric energy supplied to the plasma by the second load 2200 must be sufficient. Otherwise, problems such as the plasma not being transitioned, or the plasma turning off may occur.

Therefore, in order to smoothly perform plasma induction while excluding mutual interference between the loads described in FIGS. 6 and 7, the ignition resonant frequency f1 of the first load 2100 and the main resonant frequency f2 of the second load 2200 need to be designed more precisely, and accordingly the driving frequency change protocol of the RF generator 1000 also needs to be designed.

### 4.3 Design of Resonant Frequency of Load

Before designing the ignition resonant frequency f1 of the first load 2100, the design criteria for the main resonant frequency f2 of the second load 2200 are described.

The main resonant frequency f2 may be designed as a value obtained by adding the first value to the initial driving frequency of the RF generator 1000. Alternatively, the main resonant frequency f2 may be designed as a value that is obtained by adding the first value to the value obtained by dividing the ignition resonant frequency f1 of the first load 2100 by (2n+1).

Here, the initial driving frequency may refer to the driving frequency of the voltage signal initially applied to the load for plasma induction in the RF generator 1000 as described above. More specifically, the initial driving frequency may refer to the driving frequency of the voltage signal applied to the load by the RF generator 1000 when the plasma induction system 100 is driven. Meanwhile, the initial driving frequency may refer to the frequency set as the default in the RF generator 1000. The initial driving frequency may be determined according to the performance of the RF generator 1000.

Here, the first value may be determined arbitrarily. For example, the first value may be determined in the range of the difference value between the driving frequency determined in the process of tracking the frequency for the first load 2100 and the initial driving frequency.

The first value varies depending on the degree of difference between the first synthetic resonance frequency of the first synthetic load including the plasma and the first load 2100 and the ignition resonance frequency of the first load 2100 as the plasma is induced. Since the properties of the plasma induced are different depending on the plasma process or the design conditions of the plasma induction system 100 (e.g., the size of the discharge tube, the gas to be modified, the size of the voltage signal applied from the RF generator 1000, the basic driving frequency, or the required plasma temperature, etc.), the first value may be also different depending on the plasma process or the design conditions of the plasma induction system 100.

The first value may be determined experimentally. The method of designing the first value is described in more detail below.

For example, the first value may be determined within a range where the first condition is satisfied. The first condition is that the sum of the first current value of the current flowing in the first load 2100 and the second current value of the current flowing in the second load 2200 does not exceed the third current value of the allowable current of the RF generator 1000, when a voltage signal having an initial driving frequency is applied to the first load 2100 and the second load 2200 to ignite plasma in the RF generator 1000.

More specifically, as described below, before the plasma is ignited, the RF generator 1000 applies a voltage signal having an initial driving frequency to the first load 2100 and the second load 2200. Herein, when the first value is too small, a problem may occur, in which since the main resonant frequency f2 of the second load 2200 has a value close to the initial driving frequency, excessively large current may flow to the second load 2200 before the plasma is ignited and, as a result, the sum of the current flowing in the first load 2100 and the current flowing in the second load 2200 exceeds the maximum allowable current of the RF generator 1000.

Accordingly, the following equation must be satisfied when determining the first value.

Iₘₐᵢₙ+I_{ig}<Iₗᵢₘᵢₜ
Iig is the current flowing in the first load 2100, and satisfies the equation below:

$${I}_{i g} = \frac{{V}_{RF}}{\vert {Z}_{i g} \vert} = \frac{{V}_{RF}}{\vert {R}_{i g} + j ( {ω}_{R F} {L}_{i g} - \frac{1}{{ω}_{R F} {C}_{i g}} ) \vert}$$

wherein Rig, Lig, and Cig indicate the equivalent series resistance, inductance, and capacitance of the first load 2100, respectively.

In addition, since it is before the plasma is ignited, ORF in the above equation has a value corresponding to the initial driving frequency, and satisfies the equation below. In the equation below, fsw indicates the initial driving frequency.

ω_{RF}=2π×f_{Sw}

In addition, in the above equation, the equivalent inductance and equivalent capacitance satisfy the equation below.

$$2 π \times ( 3 {f}_{SW} ) = \frac{1}{\sqrt{{L}_{i g} {C}_{i g}}}$$

Imain indicates the current flowing in the second load 2200, and satisfies the equation below:

$${I}_{m a i n} = \frac{{V}_{R F}}{\vert {Z}_{m a i n} \vert} = \frac{{V}_{R F}}{\vert {R}_{m a i n} + j ( {ω}_{R F} {L}_{m a i n} - \frac{1}{{ω}_{R F} {C}_{m a i n}} ) \vert}$$

wherein Rmain, Lmain, and Cmain indicate the equivalent series resistance, inductance, and capacitance of the second load 2200, respectively.

In addition, the equivalent inductance and equivalent capacitance in the above equation satisfy the equation below:

$$2 π \times ( {f}_{SW} + a first value ) = \frac{1}{\sqrt{{L}_{main} {C}_{main}}}$$

Ilimit indicates the maximum allowable current of the RF generator 1000.

Meanwhile, the first condition may be used as a criterion for determining the lower limit of the first value.

As another example, the first value may be determined within a range where the second condition is satisfied. The second condition is that when a voltage signal having a first driving frequency is applied from the RF generator 1000 to the first load 2100 and the second load 2200, after the plasma is ignited and before the plasma is transitioned to the second load 2200 side, the sum of the fourth current value of the current flowing in the first load 2100 and the fifth current value of the current flowing in the second load 2200 must not exceed the third current value of the allowable current of the RF generator 1000.

More specifically, as described below, after the plasma is ignited, the RF generator 1000 applies a voltage signal having a first driving frequency to the first load 2100 and the second load 2200 for plasma transition. Here, the first driving frequency means a driving frequency adjusted as the RF generator 1000 performs frequency tracking for the first load 2100 after the plasma is ignited. Herein, when the main resonant frequency f2 of the second load 2200 is designed to be excessively close to the first driving frequency, the magnitude of the current flowing in the second load 2200 may become excessively large, which may damage the RF generator 1000. Meanwhile, as the main resonant frequency f2 of the second load 2200 differs from the first driving frequency, the magnitude of the current flowing in the second load 2200 may decrease so that the plasma is prevented from being transitioned.

Accordingly, the following equation must be satisfied in determining the first value:

Iₘₐᵢₙ+I_{ig}<Iₗᵢₘᵢₜ,Iₜᵣₐₙₛᵢₜᵢₒₙ<Iₘₐᵢₙ
wherein Iig is the current flowing in the first load 2100, and satisfies the equation below:

$${I}_{i g} = \frac{{V}_{RF}}{\vert {Z}_{i g} \vert} = \frac{{V}_{RF}}{\vert {R}_{i g} + j ( {ω}_{R F} {L}_{i g} - \frac{1}{{ω}_{R F} {C}_{i g}} ) \vert}$$

wherein Rig, Lig, and Cig represent the equivalent series resistance, inductance, and capacitance of the first load 2100, respectively.

In addition, since the plasma is ignited, ωRF in the above equation has a value corresponding to the first driving frequency, and satisfies the equation below. In the equation below, fSW represents the initial driving frequency, and β/3 represents the degree to which the driving frequency changes as frequency tracking is performed:

$${ω}_{R F} = 2 π \times ( {f}_{S W} + \frac{β}{3} )$$

In addition, the equivalent inductance and equivalent capacitance of the first load 2100 in the above equation satisfy the equation below:

$$2 π \times ( 3 {f}_{SW} ) = \frac{1}{\sqrt{{L}_{i g} {C}_{i g}}}$$

wherein Imain is the current flowing in the second load 2200, and satisfies the equation below:

$${I}_{m a i n} = \frac{{V}_{R F}}{\vert {Z}_{m a i n} \vert} = \frac{{V}_{R F}}{\vert {R}_{m a i n} + j ( {ω}_{R F} {L}_{m a i n} - \frac{1}{{ω}_{R F} {C}_{m a i n}} ) \vert}$$

wherein Rmain, Lmain, and Cmain represent the equivalent series resistance, inductance, and capacitance of the second load 2200, respectively.

In addition, in the above equation, the equivalent inductance and equivalent capacitance of the second load 2200 satisfy the equation below:

$$2 π \times ( {f}_{SW} + a first value ) = \frac{1}{\sqrt{{L}_{main} {C}_{main}}}$$

Itransition is the minimum current required for plasma to be transitioned, and may be determined based on the distance between the first load 2100 and the second load 2200, the pressure inside the discharge tube 3000, the flow rate of gas supplied into the discharge tube 3000, the type of supplied gas, etc.

Ilimit refers to the maximum allowable current of the RF generator 1000.

The second condition may be understood as a criterion for determining the upper and lower limits of the first value.

As described above, in determining the first value, at least one of the first condition and the second condition must be satisfied. In order to check whether the first condition and the second condition are satisfied, a simulation using a program or an actual experiment may be conducted.

Meanwhile, the first value may have a value within a specific range based on the initial driving frequency, the ignition resonant frequency f1, or the main resonant frequency f2. For example, the first value may be determined from a value within 0.01% to 30%, a value within 0.01% to 25%, a value within 0.01% to 20%, a value within 0.01% to 15%, a value within 0.01% to 10%, a value within 0.01% to 9%, a value within 0.01% to 8%, a value within 0.01% to 7%, a value within 0.01% to 6%, a value within 0.01% to 5%, a value within 0.01% to 4%, a value within 0.01% to 3%, a value within 0.01% to 2%, a value within 0.01% to 1%, a value within 0.01% to 0.9%, a value within 0.01% to 0.8%, a value within 0.01% to 0.7%, a value within 0.01% to 0.6%, a value within 0.01% to 0.5%, a value within 0.01% to It may be determined from a value within 0.4%, a value within 0.01% to 0.3%, a value within 0.01% to 0.2%, a value within 0.01% to 0.1%, a value within 0.05% to 10%, a value within 0.1% to 10%, a value within 0.2% to 10%, a value within 0.3% to 10%, a value within 0.4% to 10%, a value within 0.5% to 10%, a value within 0.6% to 10%, a value within 0.7% to 10%, a value within 0.8% to 10%, a value within 0.9% to 10%, a value within 1% to 10%, a value within 2% to 10%, a value within 3% to 10%, a value within 4% to 10%, and a value within 5% to 10%. As another example, the first value may be determined at a value within 0.01% to 30% of the initial driving frequency, a value within 0.01% to 25%, a value within 0.01% to 20%, a value within 0.01% to 15%, a value within 0.01% to 10%, a value within 0.01% to 9%, a value within 0.01% to 8%, a value within 0.01% to 7%, a value within 0.01% to 6%, a value within 0.01% to 5%, a value within 0.01% to 4%, a value within 0.01% to 3%, a value within 0.01% to 2%, a value within 0.01% to 1%, a value within 0.01% to 0.9%, a value within 0.01% to 0.8%, a value within 0.01% to 0.7%, a value within 0.01% to 0.6%, a value within 0.01% to 0.5%, a value within 0.01% to 0.4%, a value within 0.01% to 0.3%, a value within 0.01% to 0.2%, a value within 0.01% to 0.1%, a value within 0.05% to 10%, a value within 0.1% to 10%, a value within 0.2% to 10%, a value within 0.3% to 10%, a value within 0.4% to 10%, a value within 0.5% to 10%, a value within 0.6% to 10%, a value within 0.7% to 10%, a value within 0.8% to 10%, a value within 0.9% to 10%, a value within 1% to 10%, a value within 2% to 10%, a value within 3% to 10%, a value within 4% to 10%, a value within 5% to 10% of the main resonant frequency f2. As another example, the first value is a value within 0.01% to 30%, a value within 0.01% to 25%, a value within 0.01% to 20%, a value within 0.01% to 15%, a value within 0.01% to 10%, a value within 0.01% to 9%, a value within 0.01% to 8%, a value within 0.01% to 7%, a value within 0.01% to 6%, a value within 0.01% to 5%, a value within 0.01% to 4%, a value within 0.01% to 3%, a value within 0.01% to 2%, a value within 0.01% to 1%, a value within 0.01% to 0.9%, a value within 0.01% to 0.8%, a value within 0.01% to 0.7%, a value within 0.01% to 0.6%, a value within 0.01% to 0.5%, a value within 0.01% to 0.4%, a value within 0.01% to 0.3%, a value within 0.01% to 0.2%, a value within 0.01% to 0.1%, a value within 0.05% to 10%, a value within 0.1% to 10%, a value within 0.2% to 10%, a value within 0.3% to 10%, a value within 0.4% to 10%, a value within 0.5% to 10%, a value within 0.6% to 10%, a value within 0.7% to 10%, a value within 0.8% to 10%, a value within 0.9% to 10%, a value within 1% to 10%, a value within 2% to 10%, a values within 3% to 10%, a value within 4% to 10%, and a value within 5% to 10% of the ignition resonance frequency f1.

In the above, although it has been described that the main resonant frequency f2 is fixed according to the design of the second load 2200, the technical idea of the present disclosure is not limited thereto, and the main resonant frequency f2 may be designed to have a variable value during the plasma induction process. For example, the second load 2200 includes a variable capacitor, and the main resonant frequency f2 of the second load 2200 may be variable as the capacitance of the variable capacitor is adjusted. Herein, in the frequency tracking step S5300 for the first load 2100 described below, the capacitance of the variable capacitor is adjusted based on the electrical characteristics (e.g., voltage/current phase difference, equivalent series resistance value) of the second load 2200, and accordingly the main resonant frequency f2 of the second load 2200 may be changed.

The ignition resonant frequency f1 of the first load 2100 may be designed to be (2n+1) times the initial driving frequency of the RF generator 1000. Alternatively, the ignition resonant frequency f1 may be designed to be (2n+1) times the value that is smaller by the first value than the main resonant frequency f2.

The ignition resonance frequency f1 may be determined between (2n) times the main resonant frequency f2 and (2n+2) times the main resonant frequency. Furthermore, the ignition resonance frequency f1 may be designed to have a value closer to (2n+1) times the main resonant frequency, rather than (2n) times the main resonant frequency f2 or (2n+2) times the main resonant frequency.

Meanwhile, in designing the ignition resonance frequency f1, when a voltage signal having an initial driving frequency is applied from the RF generator 1000 to the first load 2100 and the second load 2200, the condition that the sum of the magnitudes of the current flowing in the first load 2100 and the magnitudes of the current flowing in the second load 2200 is smaller than the maximum allowable current value of the RF generator 1000 may be further considered.

### 4.4 Control Method

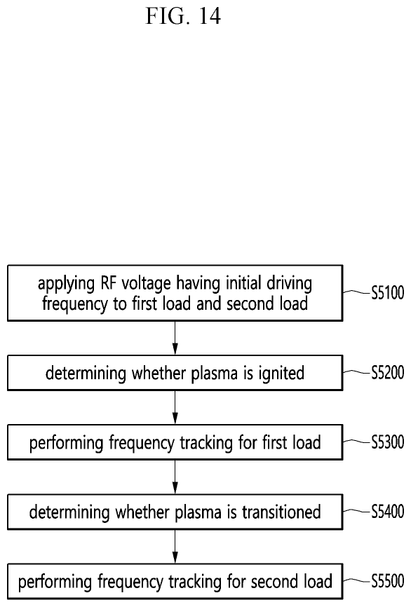

Hereinafter, with reference to FIG. 14, the process of controlling a plasma induction system 100 using multiple loads and one RF generator 1000 will be described.

FIG. 14 is a flowchart illustrating the process of operating a plasma induction system 100 according to an embodiment.

Referring to FIG. 14, the plasma induction system 100 may include a step of applying an RF voltage having an initial driving frequency to a first load 2100 and a second load 2200 (S5100), a step of determining whether plasma is ignited (S5200), a step of performing frequency tracking for the first load 2100 (S5300), a step of determining whether the plasma is transitioned (S5400), and a step of performing frequency tracking for the second load (S5500).

Each step is described in detail below.

The RF generator 1000 may apply a voltage signal having the initial driving frequency to the first load 2100 and the second load 2200 (S5100). For example, the RF generator 1000 may configure a value obtained by dividing the ignition resonance frequency f1 of the first load 2100 by (2n+1) as the initial driving frequency, and output a voltage signal having the initial driving frequency.

The RF generator 1000 may determine whether plasma is ignited (S5200). Since step S5200 is the same as step S1300 described above, any duplicate content will be omitted. In determining whether the plasma is ignited, a switch signal generated by a control unit 1600 is acquired as voltage phase information, and current phase information may be acquired from a first phase sensing module 1401. Alternatively, information acquired from a power sensing module 1500 or information acquired from a first power sensing module may be used to determine whether the plasma is ignited.

When it is determined that the plasma is ignited, frequency tracking may be performed for the first load 2100 (S5300). For example, the RF generator 1000 may change the driving frequency to approach the first synthetic resonant frequency of the first synthetic load including the first load 2100 and the plasma. The frequency tracking method for the first load 2100 may utilize the harmonic frequency tracking method and/or the power consumption-based frequency tracking method described above.

The first synthetic resonance frequency may be greater than the ignition resonance frequency f1. Herein, the difference between the value obtained by dividing the first synthetic resonance frequency by (2n+1) and the initial driving frequency may correspond to the first value.

Meanwhile, the first synthetic resonant frequency may be obtained as the driving frequency of the voltage signal output from the RF generator 1000 when the difference between the phase of the current flowing in the first load 2100 and the phase of the voltage applied to the first load 2100 is 0 or substantially equal to 0.

Next, it may be determined whether the plasma is transitioned (S5400). Since step S5400 is the same as step S1600 described above, any duplicate content will be omitted. In determining whether the plasma is transitioned, a switch signal generated by the control unit 1600 may be acquired as voltage phase information, and current phase information may be acquired from a second phase sensing module 1402. Alternatively, information acquired from a power sensing module 1500 or information acquired from a second power sensing module may be used to determine whether the plasma is transitioned.

When it is determined that the plasma has been transitioned, frequency tracking for the second load 2200 may be performed (S5500). For example, the RF generator 1000 may change the driving frequency to approach the second synthetic resonance frequency of the second synthetic load including the second load 2200 and the plasma. The frequency tracking method for the second load 2200 may be the aforementioned frequency tracking method and/or the power consumption-based frequency tracking method.

The second synthetic resonant frequency may be greater than the main resonant frequency f2. Herein, the difference between the value obtained by dividing the first synthetic resonant frequency by (2n+1) and the second synthetic resonant frequency may be greater than or equal to the threshold value. Here, when the plasma induction system 100 is in a normal state, that is, when frequency tracking for the second load 2200 is performed, the threshold value may be understood as a threshold value for allowing a relatively low current to flow to the first load 2100. The threshold value may be determined, for example, to be more than or equal to about 10% of the initial driving frequency.

Meanwhile, the resonant frequency of the second synthetic load may be obtained as the driving frequency of the voltage signal output from the RF generator 1000 when the difference between the phase of the current flowing in the second load 2200 and the phase of the voltage applied to the second load 2200 is 0 or substantially equal to 0.

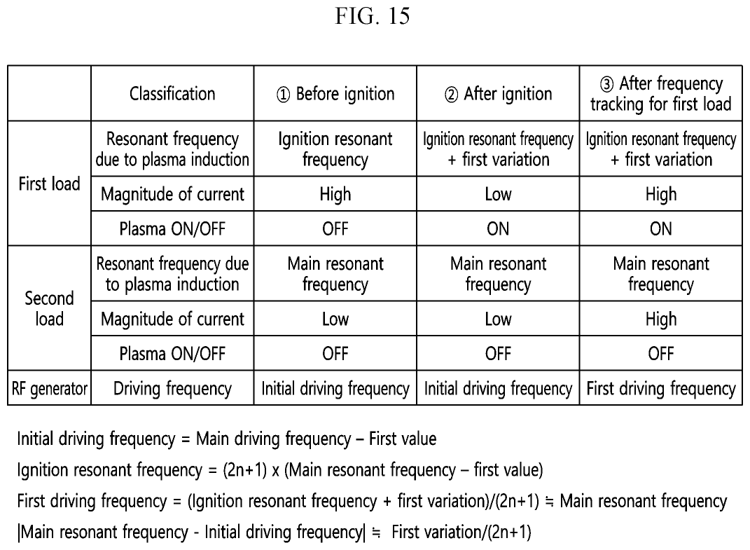

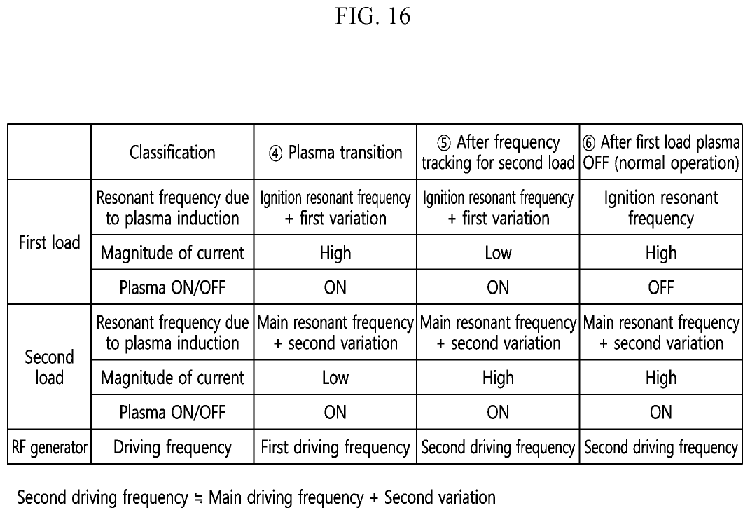

Hereinafter, with reference to FIGS. 15 and 16, the process in which the electrical characteristics of the first load 2100 and the second load 2200 change as the plasma is ignited and maintained, and the process in which the driving frequency of the RF generator 1000 changes are described.

FIG. 15 and FIG. 16 are diagrams showing the characteristics of components in a plasma induction system 100 due to plasma induction according to an embodiment. FIG. 15 and FIG. 16 illustrate the change process of the resonance frequency, the current size, and on/off of the plasma due to plasma induction for each of the first load 2100 and the second load 2200, and the change process of the driving frequency for the RF generator 1000. Here, the resonance frequency due to plasma induction means the resonance frequency of the composite load including the load and the plasma. In addition, the current size means the magnitude of the current flowing in each load, and the plasma on/off indicates whether the plasma is on or off in the area corresponding to each load.

### [Before Plasma Ignition]

First, a voltage signal having an initial driving frequency may be applied to each of the first load 2100 and the second load 2200 by the RF generator 1000 before plasma ignition. The initial driving frequency is a value obtained by subtracting the first value from the main resonant frequency, and may be a value equal to or close to the value obtained by dividing the ignition resonant frequency by (2n+1).

The magnitude of the current flowing in the first load 2100 before the plasma is ignited may be relatively large. This is because the ignition resonance frequency of the first load 2100 is a harmonic of the initial driving frequency, so that a high current flows to the first load 2100 due to the harmonic component of the voltage signal.

Meanwhile, the magnitude of the current flowing in the second load 2200 may be relatively small until the plasma is ignited. This is because the initial driving frequency is different from the main resonant frequency and thus the second load 2200 is not in the resonant state.

Since the plasma is still not ignited, the resonant frequency due to plasma induction is the ignition resonant frequency for the first load 2100 and the main resonant frequency for the second load 2200.

In addition, the plasma is off in the first region R1 and the second region R2.

[after Plasma Ignition]

When plasma is ignited, the resonance frequency due to plasma induction in the first load 2100, i.e., the resonance frequency of the first composite load including the plasma and the first load 2100, may be changed to a value obtained by adding a first variation to the ignition resonance frequency. Here, the first variation refers to the degree to which the resonance frequency of the first load 2100 viewed from the output terminals of the RF generator 1000 changes as the plasma is ignited. The first variation may be about 1% to about 10% of the ignition resonance frequency f1. However, it should be noted that the first variation value may not be limited to the above value depending on the usage environment or design of the plasma induction system 100.

When the plasma is ignited, the current flowing in the first load 2100 is momentarily reduced. This is because the influence of the harmonic components of the voltage signal having the initial driving frequency is also reduced as the resonant frequency of the first synthetic load changes.

In the case of the second load 2200, since it is not greatly affected by the ignited plasma, the resonant frequency due to plasma induction is still the main resonant frequency, and the current is also relatively low.

[after Frequency Tracking for the First Load]

As plasma is induced on the first load 2100, a phase difference occurs between the current flowing in the first load 2100 and the voltage applied to the first load 2100, and the RF generator 1000 changes the driving frequency to the first driving frequency to compensate for this.

Here, the first driving frequency may mean a frequency determined by the harmonic frequency tracking method or the power consumption-based frequency tracking method. The first driving frequency is close to the value obtained by dividing an addition of the first variation to the ignition resonance frequency by (2n+1).

When a voltage signal having a first driving frequency is applied to the first load 2100, the first load 2100 may enter a resonant state so that the amount of current flowing may increase.

The main resonant frequency of the second load 2200 may be designed to be substantially the same as or close to the first driving frequency. Therefore, as a voltage signal having a first driving frequency is applied to the second load 2200, the second load 2200 may operate in a resonant state so that the amount of the flowing current may increase.

Meanwhile, the difference between the main resonant frequency and the initial driving frequency may be substantially equal to or close to the value obtained by dividing the first change by (2n+1).

### [Plasma Transition]

When the frequency of the voltage signal provided by the RF generator 1000 becomes the first driving frequency which is substantially the same as or similar to the main resonant frequency f2 of the second load 2200, the intensity of the electromagnetic field formed in the second region R2 by the second load 2200 also increases. Accordingly, the plasma ignited in the first region R1 moves to the second region R2.

When the plasma moves to the second region R2, the resonance frequency due to plasma induction for the second load 2200 (i.e., the resonance frequency of the second composite load including the second load 2200 and the plasma), changes by the second variation amount by the plasma. Here, the second variation amount means the degree to which the resonance frequency of the second load 2200 as viewed from the output terminals of the RF generator 1000 changes as the plasma is transitioned. The second variation amount may be about 1% to about 10% of the main resonant frequency f2. However, it is obvious that the second variation amount value may not be limited to the above value depending on the usage environment or design of the plasma induction system 100.

As the plasma is induced in the second region R2, the magnitude of the current flowing in the second load 2200 decreases momentarily. This is because the amount of energy transferred by the voltage signal having the first driving frequency decreases as the resonant frequency of the second synthetic load changes.

Meanwhile, even if the plasma moves to the second region R2, the plasma may be maintained in the first region R1.

This is because, as described above, the first driving frequency of the voltage signal output from the RF generator 1000 is substantially the same as or similar to the resonant frequency of the first synthetic load.

[Frequency Tracking after Plasma Transition]

As plasma is induced on the second load 2200 side (in the second region), a phase difference occurs between the current and voltage for the second load 2200, and the RF generator 1000 may change the driving frequency to the second driving frequency to compensate for this. Here, the second driving frequency may mean a frequency determined according to a frequency tracking method or a power consumption-based frequency tracking method. The second driving frequency approaches a value that adds a second variation to the main resonant frequency. For example, the second driving frequency may have a value greater than the first driving frequency.

As a voltage signal having the second driving frequency is applied to the second load 2200, the second load 2200 enters a resonant state and the magnitude of the flowing current may increase.

Meanwhile, for the first load 2100, the voltage signal applied has the second driving frequency, which is different from the resonant frequency of the first synthetic load (e.g., has a larger value), so the magnitude of the current flowing in the first load 2100 decreases. Accordingly, the size of the plasma may decrease or the plasma may not be maintained in the first region R1.

### [Plasma Maintenance (Steady State)]

As frequency tracking is performed for the second load 2200, the plasma may be stably maintained in the second region R2. Specifically, according to frequency tracking for the second load 2200, a voltage signal having a driving frequency corresponding to the resonant frequency of the second load 2200 and the second synthetic load including the plasma is continuously applied to the second load 2200, and accordingly, the energy supplied to the plasma (energy by the electromagnetic field) is maintained high, so that the plasma is stably maintained.

Meanwhile, in the case of the first load 2100, the plasma is turned off in the first region R1, and accordingly, the resonance frequency due to plasma induction returns to the ignition resonance frequency. Since the ignition resonance frequency and the second driving frequency have a sufficient difference (e.g., a difference between the ignition resonance frequency f1 and the second driving frequency may be between about 1% and about 10% of the second driving frequency, but may vary depending on the usage environment or design of the plasma induction system 100), the energy (or the intensity of the electromagnetic field) supplied to the first region R1 by the first load 2100 becomes very low. Accordingly, it does not affect the plasma that is stably maintained in the second region R2.

In the foregoing, the method of operating the plasma induction system 100 including multiple loads and one RF generator 1000 is described. Since the ignition resonant frequency of the first load 2100 and the main resonant frequency of the second load 2200 are designed to differ significantly in the plasma induction system 100 described above, there is less risk of induced electromotive force occurring between them, and plasma ignition, plasma transition, and plasma maintenance are performed in a time series manner, enabling stable plasma induction. Furthermore, since only one RF generator 1000 is used, the manufacturing cost is lowered, the manufacturing process is simplified, and the volume of the product is reduced, whereby it is judged that there will be a significant effect in terms of product competitiveness.

The features, structures, effects, etc. described in the embodiments above are included in at least one embodiment of the present invention, and are not necessarily limited to only one embodiment. Furthermore, the features, structures, effects, etc. exemplified in each embodiment may be combined or modified and implemented in other embodiments by a person having ordinary knowledge in the field to which the embodiments belong. Therefore, the contents related to such combinations and modifications should be interpreted as being included in the scope of the present invention.

In addition, although the above description focuses on the embodiments, this is only an example and does not limit the present invention, and those with ordinary knowledge in the field to which the present invention pertains will be able to recognize that various modifications and applications not exemplified above are possible without departing from the essential characteristics of the present embodiments. That is, each component specifically shown in the embodiments may be modified and implemented. In addition, the differences related to such modifications and applications should be interpreted as being included in the scope of the present invention defined in the appended claims.

What is claimed is:

1. An apparatus for inducing plasma, the apparatus comprising:
a discharge tube configured to provide a space where the plasma is induced;
a first load comprising an ignition antenna structure configured to be disposed to surround the discharge tube and at least one capacitive element configured to be electrically connected in series with the ignition antenna structure;
a second load comprising a main antenna structure configured to be disposed to surround the discharge tube and configured to be disposed within a predetermined distance along a direction parallel to a central axis of the discharge tube from the ignition antenna structure, and at least one capacitive element configured to be electrically connected in series with the main antenna structure; and
an RF generator configured to apply RF (Radio Frequency) voltage to the first load and the second load;
wherein the first load is designed to have an ignition resonant frequency corresponding to (2n+1) times an initial driving frequency that differs from the main resonant frequency by a first value (n is a natural number) when the second load is designed to have a main resonant frequency, and
wherein the RF generator is configured to apply RF voltage having the initial driving frequency to the first load and the second load for igniting the plasma.

2. The apparatus of claim 1,
wherein after plasma is ignited in a plasma ignition region corresponding to the ignition antenna structure within the discharge tube, a magnitude of current flowing in the ignition antenna structure is greater when RF voltage having a first driving frequency is applied to the ignition antenna structure compared to when RF voltage having the initial driving frequency is applied to the ignition antenna structure, and
wherein the first driving frequency is greater than the initial driving frequency.

3. The apparatus of claim 2,
wherein the main antenna structure is applied with RF voltage having the same driving frequency as RF voltage applied to the ignition antenna structure, and
wherein a magnitude of current flowing in the main antenna structure is greater when RF power with the first driving frequency is applied to the main antenna structure compared to when RF power with the initial driving frequency is applied to the main antenna structure.

4. The apparatus of claim 3,
wherein after the ignited plasma transitions into a plasma maintenance region corresponding to the main antenna structure within the discharge tube, the magnitude of the current flowing in the main antenna structure is greater when RF power having a second driving frequency is applied to the main antenna structure compared to when RF power having the first driving frequency is applied to the main antenna structure, and
wherein the second driving frequency is greater than the first driving frequency.

5. The apparatus of claim 4,
wherein the ignition antenna structure is applied with RF voltage having driving frequency same as RF voltage applied to the main antenna structure, and
wherein the magnitude of the current flowing in the ignition antenna structure is smaller when RF power having the second driving frequency is applied to the ignition antenna structure compared to when RF power having the first driving frequency is applied to the ignition antenna structure.

6. The apparatus of claim of 1,
wherein when the plasma is ignited in a plasma ignition region corresponding to the ignition antenna structure within the discharge tube, the ignited plasma and a first equivalent load comprising the first load have a first equivalent resonant frequency greater than the ignition resonance frequency, and
wherein a first difference value obtained by subtracting the initial driving frequency from a value obtained by dividing the first equivalent resonant frequency by (2n+1) corresponds to the first value.

7. The apparatus of claim 6,
wherein when the ignited plasma transitions into a plasma maintenance region corresponding to the main antenna structure within the discharge tube, the transitioned plasma and a second equivalent load comprising the second load have a second equivalent resonant frequency greater than the main resonant frequency, and
wherein a second difference value obtained by subtracting the second equivalent resonant frequency from a value obtained by dividing the first equivalent resonant frequency by (2n+1) is more than or equal to a threshold value.

8. The apparatus of claim 7,
wherein the threshold value is determined to be more than or equal to 10% of the initial driving frequency.

9. The apparatus of claim 6,
wherein when the RF generator applies voltage signal having a driving frequency corresponding to the first equivalent resonant frequency to the first load in a state where the plasma is ignited, a difference between a phase of voltage applied to the first load and a phase of current flowing in the first load is 0 or substantially 0.

10. The apparatus of claim 7,
wherein when the RF generator applies voltage signal having a driving frequency corresponding to the second equivalent resonant frequency to the second load in a state where the plasma is transitioned, a difference between a phase of voltage applied to the second load and a phase of current flowing in the second load is 0 or substantially 0.

11. The apparatus of claim 1,
wherein when a base driving frequency of voltage signal output by the RF generator is a, a magnitude of the first value is determined within the range of 0.01*a to 0.3*a.

12. The apparatus of claim 1,
wherein the main resonant frequency has a value between 1.01 times and 1.1 times the initial driving frequency.

13. The apparatus of claim 1,
wherein the predetermined distance is within 10 cm.

14. A method of inducing plasma for supplying power to an apparatus for inducing plasma,
the apparatus comprising:
a discharge tube configured to provide a space where the plasma is induced;
a first load comprising an ignition antenna structure configured to be disposed to surround the discharge tube and at least one capacitive element configured to be electrically connected in series with the ignition antenna structure;
a second load comprising a main antenna structure configured to be disposed to surround the discharge tube and configured to be disposed within a predetermined distance along a direction parallel to central axis of the discharge tube from the ignition antenna structure, and at least one capacitive element configured to be electrically connected in series with the main antenna structure; and
an RF generator configured to apply RF (Radio Frequency) voltage to the first load and the second load;
the method comprising:
applying an initial RF voltage having an initial driving frequency to the first load and the second load using the RF generator;
applying a first RF voltage having a first driving frequency to the first load and the second load after detecting that plasma is ignited in a plasma ignition region corresponding to the ignition antenna structure within the discharge tube,
wherein the first driving frequency is determined based on a phase difference of voltage and current applied to the first load, and
wherein a magnitude of current flowing in the main antenna structure is increased when the first RF voltage is applied to the second load compared to when the initial RF voltage is applied to the second load; and
applying a second RF voltage having a second driving frequency to the first load and the second load after detecting that the ignited plasma is transitioned into a plasma maintenance region corresponding to the main antenna structure within the discharge tube,
wherein the second driving frequency is determined based on a phase difference of voltage and current applied to the second load, and
wherein a magnitude of the current flowing in the ignition antenna structure is decreased when the second RF voltage is applied to the first load compared to when the first RF voltage is applied to the first load.

15. An apparatus for inducing plasma, the apparatus comprising:
a discharge tube configured to provide a space where the plasma is induced;
a first load comprising an ignition antenna structure configured to be disposed to surround the discharge tube and at least one capacitive element configured to be electrically connected in series with the ignition antenna structure;
a second load comprising a main antenna structure configured to be disposed to surround the discharge tube and configured to be disposed within a predetermined distance along a direction parallel to a central axis of the discharge tube from the ignition antenna structure, and at least one capacitive element configured to be electrically connected in series with the main antenna structure; and
an RF generator configured to apply RF (Radio Frequency) voltage to the first load and the second load,
wherein when the second load is designed to have a main resonant frequency, an ignition resonant frequency of the first load is designed to be close to (2n+1) times the main resonant frequency, rather than (2n) times the main resonant frequency or (2n+2) times the main resonant frequency, and
wherein n is a natural number.
